(19) United States
(12) Patent Application Publication
(10) Pub. No.: US 2026/0193459 A1
(43) Pub. Date: Jul. 9, 2026

(54) CHEMICAL-RESISTANT PROTECTIVE FILM

(71) Applicant: NISSAN CHEMICAL CORPORATION, Tokyo (JP)

(72) Inventors: Tokio NISHITA, Toyama-shi (JP); Kazuhiko KINOSHITA, Toyama-shi (JP)

(73) Assignee: NISSAN CHEMICAL CORPORATION, Tokyo (JP)

(21) Appl. No.: 18/867,947

(22) PCT Filed: Apr. 25, 2023
(86) PCT No.: PCT/JP2023/016224

§ 371 Date: Nov. 21, 2024

(30) Foreign Application Priority Data
May 24, 2022 (JP) 2022-084722

(51) Int. Cl. C08L 63/04; C08G 59/32; C08G 59/50; C08G 59/64; C08K 5/053; G03F 7/11; H10P 50/00; H10P 50/64; H10P 50/66; H10P 50/68; H10P 70/00; H10P 76/20

(52) U.S. Cl. CPC C08L 63/04; C08G 59/32; C08G 59/5073; C08G 59/64; C08K 5/053; G03F 7/11; H10P 50/692; H10P 50/695; H10P 50/71; H10P 50/73; H10P 70/23; H10P 70/27; H10P 76/2042; C08L 2203/206; H10P 50/646; H10P 50/667; H10P 50/683

(57) ABSTRACT

A composition for forming a protective film against a wet etching solution for a semiconductor, the composition containing: a compound or polymer having a reactive group capable of undergoing a crosslinking reaction in the presence of a curing agent; a curing agent; a compound having a hydroxy group and at least one of a hydroxy group and a carbonyl group; and a solvent.

### TECHNICAL FIELD

The present invention relates to a composition for forming a protective film having excellent resistance particularly to a wet etching solution for a semiconductor in a lithography process in manufacturing a semiconductor. In addition, the present invention relates to a protective film formed of the composition, a method for manufacturing a substrate with a resist pattern onto which the protective film is applied, and a method for manufacturing a semiconductor device.

### BACKGROUND ART

In manufacturing a semiconductor, a lithography process for forming a resist pattern having a desired shape by providing a resist underlayer film between a substrate and a resist film formed on the substrate is widely known. The substrate is processed after the resist pattern is formed, and dry etching is mainly used as a process thereof, but wet etching may be used depending on the kind of the substrate. Patent Literature 1 discloses a resist underlayer film material having resistance to aqueous alkaline hydrogen peroxide.

### CITATION LIST

### Patent Literature

Patent Literature 1: JP 2018-173520 A

### SUMMARY OF INVENTION

### Technical Problem

In a case where a protective film of a semiconductor substrate is formed using a composition for forming a protective film and a base substrate is processed by wet etching using the protective film as an etching mask, the protective film is required to have an excellent mask function (that is, the masked portion can protect the substrate) against a wet etching solution for a semiconductor.

Furthermore, there is also a demand for a composition for forming a protective film that has excellent coatability even on a so-called stepped substrate, has a small difference in film thickness after embedding, and can form a flat film.

In the related art, in order to develop resistance to SC-1 (an ammonia-hydrogen peroxide solution) which is a kind of wet etching chemical liquid, a method of applying a low molecular compound (for example, gallic acid) as an additive has been used, but there is a limit to solving the above problems.

Furthermore, the protective film used for the above object is expected to have a function as a resist underlayer film for solving a trouble (shape defect or the like) at the time of forming a so-called resist pattern.

The present invention has been made in view of the above circumstances, and an object of the present invention is to provide a composition for forming a protective film that can form a protective film having excellent resistance to a wet etching solution for a semiconductor, and can also be effectively used as a composition for forming a resist underlayer film.

### Solution to Problem

As a result of intensive studies to solve the above problems, the present inventors have found that a film obtained using a composition for forming a protective film containing a compound or polymer having a reactive group capable of undergoing a crosslinking reaction in the presence of a curing agent, a curing agent, and a specific compound has excellent chemical resistance, thereby completing the present invention.

That is, the present invention encompasses the following aspects.

[1] A composition for forming a protective film against a wet etching solution for a semiconductor, the composition containing:
(A) a compound or polymer having a reactive group capable of undergoing a crosslinking reaction in the presence of a curing agent;
(B) a curing agent;
(C) a compound having a hydroxy group and at least one of a hydroxy group and a carbonyl group; and
(D) a solvent.

[2] The composition for forming a protective film according to [1], further containing (E) a compound or polymer having a phenolic hydroxy group.

[3] The composition for forming a protective film according to [1] or [2], in which the curing agent is a base.

[4] The composition for forming a protective film according to [3], in which the base is an imidazole-based compound.

[5] The composition for forming a protective film according to [4], in which the base is represented by the following Formula (B1):

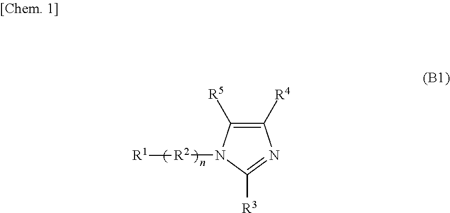

(in Formula (B1), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or fewer carbon atoms, which may be substituted, R⁵ represents a hydrogen atom, a formyl group, an alkyl group having 1 to 4 carbon atoms, which may be substituted, or an alkoxyalkyl group having 4 or fewer carbon atoms, which may be substituted, and n represents 0 or 1).

[6] The composition for forming a protective film according to any one of [1] to [5], in which the compound (C) is at least one of a compound represented by the following Formula (C-1), a compound represented by the following Formula (C-2), and a compound represented by the following Formula (C-3):

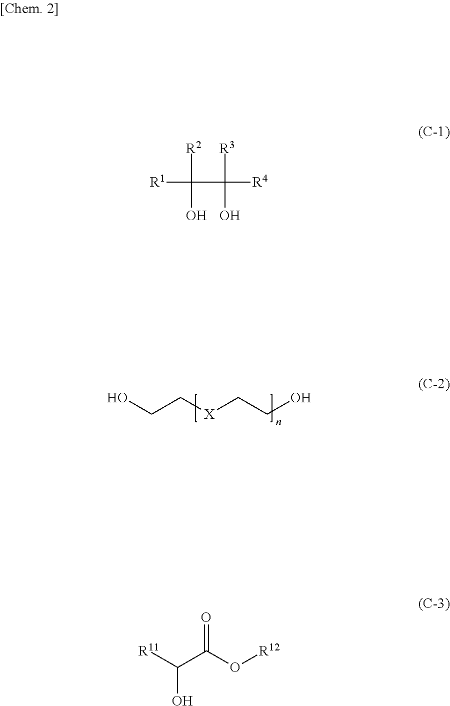

(in Formula (C-1), R¹ to R⁴ each independently represent a hydrogen atom, an alkyl group having 1 to 6 carbon atoms, or a hydroxyalkyl group having 1 to 6 carbon atoms,
in Formula (C-2), X represents —O— or —NR— (R represents a hydrogen atom, an alkyl group having 1 to 6 carbon atoms, which may have a hydroxy group, an aryl group having 6 to 12 carbon atoms, which may have a substituent, or an aralkyl group having 7 to 13 carbon atoms, which may have a substituent), n represents an integer from 1 to 3, and when n is 2 or 3, X may be the same or different, and
in Formula (C-3), R¹¹ represents an alkyl group having 1 to 4 carbon atoms, and R¹² represents an alkyl group having 1 to 6 carbon atoms).

[7] The composition for forming a protective film according to any one of [1] to [6], in which a content of the compound (C) is 1 to 30 mass % with respect to the compound or polymer (A).

[8] The composition for forming a protective film according to any one of [1] to [7], in which the compound or polymer (A) is a compound or polymer containing a cyclic ether having a 3-membered ring structure or a 4-membered ring structure.

[9] The composition for forming a protective film according to [8], in which
the compound (A) is a compound that does not have a repeating structural unit,
the compound has a terminal group (A1), a polyvalent group (A2), and a linking group (A3),
the terminal group (A1) is bonded only to the linking group (A3),
the polyvalent group (A2) is bonded only to the linking group (A3),
the linking group (A3) is bonded on one hand to the terminal group (A1) and on the other hand to the polyvalent group (A2), and may optionally be bonded to another linking group (A3),
the terminal group (A1) has any of structures of the following Formula (I):

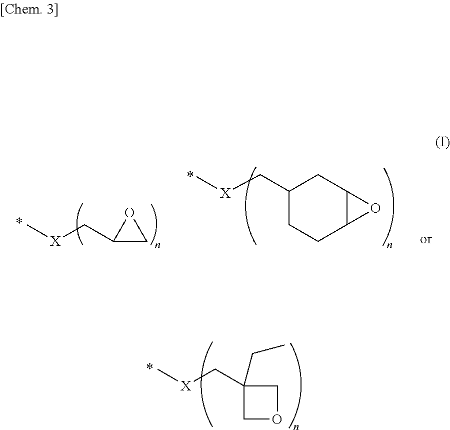

(in Formula (I), * represents a binding site to the linking group (A3), and
X represents an ether bond, an ester bond, or a nitrogen atom, in which n=1 when X is an ether bond or an ester bond, and n=2 when X is a nitrogen atom),
the polyvalent group (A2) is a divalent to tetravalent group selected from the group consisting of:
—O—;
an aliphatic hydrocarbon group;
a combination of an aromatic hydrocarbon group having fewer than 10 carbon atoms and an aliphatic hydrocarbon group; and
a combination of an aromatic hydrocarbon group having 10 or more carbon atoms and —O—, and
the linking group (A3) represents an aromatic hydrocarbon group.

[10] The composition for forming a protective film according to [9], in which the compound (A) is a compound represented by the following Formula (II):

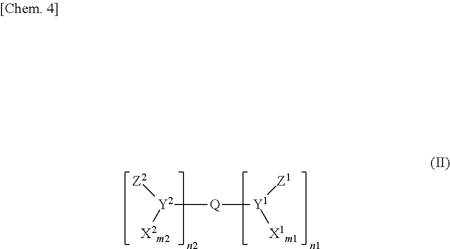

(in Formula (II),
Z¹ and Z² each independently represent

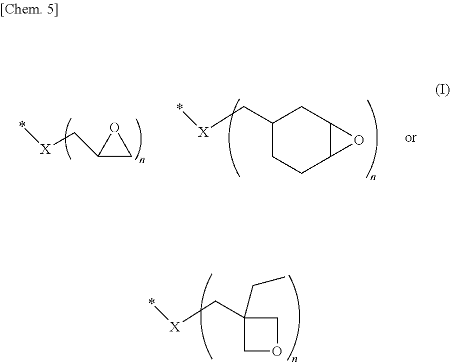

(in Formula (I), * represents Y¹ or a binding site to Y², and
X represents an ether bond, an ester bond, or a nitrogen atom, in which n=1 when X is an ether bond or an ester bond, and n=2 when X is a nitrogen atom),
Y¹ and Y² each independently represent an aromatic hydrocarbon group,
X¹ and X² each independently represent —Y¹—Z¹ or —Y²—Z²,
n1 and n2 each independently represent an integer from 0 to 4, where any one of n1 and n2 is 1 or more,
m1 defined in (X¹)m1 represents 0 or 1,
m2 defined in (X²)m2 represents 0 or 1, and
Q represents a (n1+n2)-valent group selected from the group consisting of —O—, an aliphatic hydrocarbon group, a combination of an aromatic hydrocarbon group having fewer than 10 carbon atoms and an aliphatic hydrocarbon group, and a combination of an aromatic hydrocarbon group having 10 or more carbon atoms and —O—).

[11] The composition for forming a protective film according to [9], in which the compound (A) is a compound having a partial structure represented by the following Formula (III):

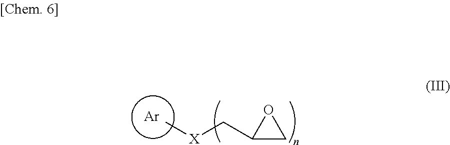

(in Formula (III), Ar represents a benzene ring, a naphthalene ring, or an anthracene ring, and X represents an ether bond, an ester bond, or a nitrogen atom, in which n=1 when X is an ether bond or an ester bond, and n=2 when X is a nitrogen atom).

[12] The composition for forming a protective film according to [8], in which the polymer (A) is a polymer having a unit structure represented by the following Formula (1-1):

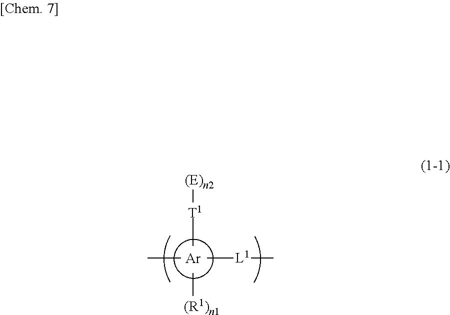

(in Formula (1-1), Ar represents a benzene ring, a naphthalene ring, or an anthracene ring, R¹ represents a hydroxy group, a mercapto group which may be protected by a methyl group, an amino group which may be protected by a methyl group, a halogeno group, or an alkyl group having 1 to 10 carbon atoms, which may be substituted with or interrupted by a heteroatom and may be substituted with a hydroxy group, n1 represents an integer from 0 to 3, L¹ represents a single bond or an alkylene group having 1 to 10 carbon atoms, n2 represents 1 or 2, E represents a group having an epoxy group or a group having an oxetanyl group, T¹ represents a single bond, an ether bond, or an alkylene group having 1 to 10 carbon atoms, which may be interrupted by an ester bond or an amide bond, when n2=1, and T¹ represents a nitrogen atom or an amide bond when n2=2).

[13] The composition for forming a protective film according to any one of [2] to [12], in which the compound or polymer having a phenolic hydroxy group (E) has two or more phenolic hydroxy groups.

[14] The composition for forming a protective film according to any one of [2] to [13], in which the compound or polymer having a phenolic hydroxy group (E) is represented by the following Formula (2-1):

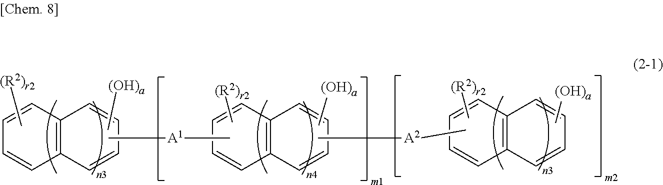

(in Formula (2-1), R²'s each independently represent a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, A¹ and A² each independently represent an alkylene group having 1 to 10 carbon atoms, a divalent organic group derived from a bicyclo ring compound, a biphenylene group or a divalent organic group represented by —C(T²)(T³)-, or a combination thereof, T² represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, and T³ represents a hydrogen atom or a monovalent group represented by Formula (2-1-a)),

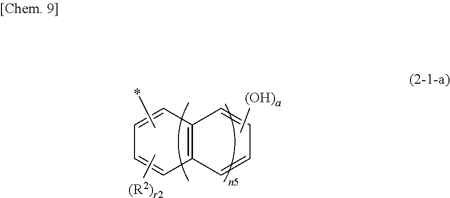

(* in Formula (2-1-a) represents a binding site to a carbon atom to which T³ is bonded,
R² has the same meaning as R² in Formula (2-1), a represents an integer from 1 to 6, n3 to n5 each independently represent an integer from 0 to 2, r2 represents an integer from 0 to 3, and m1 and m2 each independently represent a number from 0 to 10,000,000).

[15] The composition for forming a protective film according to any one of [2] to [13], in which the compound or polymer having a phenolic hydroxy group (E) is a compound represented by the following Formula (2-2):

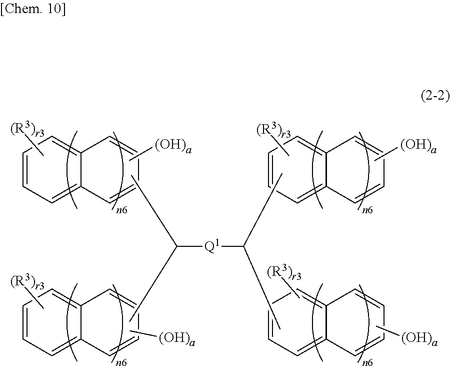

(in Formula (2-2), R³ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, Q¹ represents a single bond, an oxygen atom, a sulfur atom, a sulfonyl group, a carbonyl group, an imino group, an arylene group having 6 to 40 carbon atoms, or an alkylene group having 1 to 10 carbon atoms, which may be substituted with a halogeno group, a represents an integer from 1 to 6, n6 represents an integer from 0 to 2, and r3 represents an integer from 0 to 3).

[16] The composition for forming a protective film according to any one of [2] to [13], in which the compound or polymer having a phenolic hydroxy group (E) is a polymer having a unit structure represented by the following Formula (3-1):

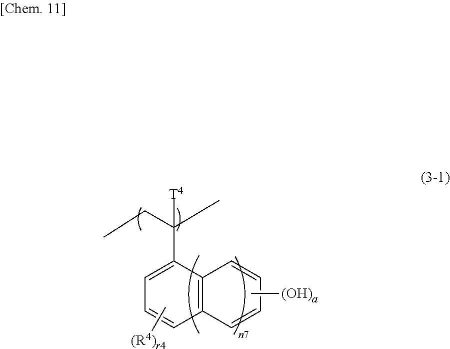

(in Formula (3-1), T⁴ represents a hydrogen atom or an alkyl group having 1 to 10 carbon atoms, which may be substituted with a halogeno group, R⁴ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, r4 represents an integer from 0 to 3, n7 represents an integer from 0 to 2, and a represents an integer from 1 to 6).

[17] A protective film against a wet etching solution for a semiconductor, which is a baked product of a coating film formed of the composition for forming a protective film according to any one of [1] to [16].

[18] A composition for forming a resist underlayer film, the composition containing:
(A) a compound or polymer having a reactive group capable of undergoing a crosslinking reaction in the presence of a curing agent;
(B) a curing agent;
(C) a compound having a hydroxy group and at least one of a hydroxy group and a carbonyl group; and
(D) a solvent.

[19] The composition for forming a resist underlayer film according to [18], further containing (E) a compound or polymer having a phenolic hydroxy group.

[20] The composition for forming a resist underlayer film according to [18] or [19], in which the curing agent is a base.

[21] The composition for forming a resist underlayer film according to [20], in which the base is an imidazole-based compound.

[22] The composition for forming a resist underlayer film according to [21], in which the base is represented by the following Formula (B1):

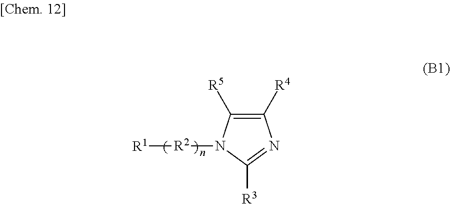

(in Formula (B1), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or fewer carbon atoms, which may be substituted, R⁵ represents a hydrogen atom, a formyl group, an alkyl group having 1 to 4 carbon atoms, which may be substituted, or an alkoxyalkyl group having 4 or fewer carbon atoms, which may be substituted, and n represents 0 or 1).

[23] The composition for forming a resist underlayer film according to any one of [18] to [22], in which the compound (C) is at least one of a compound represented by the following Formula (C-1), a compound represented by the following Formula (C-2), and a compound represented by the following Formula (C-3):

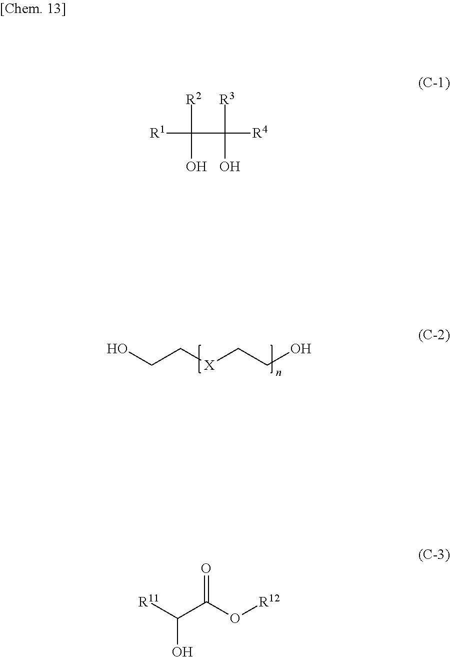

(in Formula (C-1), R¹ to R⁴ each independently represent a hydrogen atom, an alkyl group having 1 to 6 carbon atoms, or a hydroxyalkyl group having 1 to 6 carbon atoms,
in Formula (C-2), X represents —O— or —NR— (R represents a hydrogen atom, an alkyl group having 1 to 6 carbon atoms, which may have a hydroxy group, an aryl group having 6 to 12 carbon atoms, which may have a substituent, or an aralkyl group having 7 to 13 carbon atoms, which may have a substituent), n represents an integer from 1 to 3, and when n is 2 or 3, X may be the same or different, and
in Formula (C-3), R¹¹ represents an alkyl group having 1 to 4 carbon atoms, and R¹² represents an alkyl group having 1 to 6 carbon atoms).

[24] The composition for forming a resist underlayer film according to any one of [18] to [23], in which a content of the compound (C) is 1 to 30 mass % with respect to the compound or polymer (A).

[25] The composition for forming a resist underlayer film according to any one of [18] to [24], in which the compound or polymer (A) is a compound or polymer containing a cyclic ether having a 3-membered ring structure or a 4-membered ring structure.

[26] A resist underlayer film which is a baked product of a coating film formed of the composition for forming a resist underlayer film according to any one of [18] to [25].

[27] A method for manufacturing a substrate with a protective film, the method including: applying the composition for forming a protective film according to any one of [1] to [16] onto a stepped semiconductor substrate and baking the composition to form a protective film, in which the method is used for manufacturing a semiconductor.

[28] A method for manufacturing a substrate with a resist pattern, the method including: applying the composition for forming a protective film according to any one of [1] to [16] or the composition for forming a resist underlayer film according to any one of [18] to [25] onto a semiconductor substrate and baking the composition to form a protective film as a resist underlayer film; and forming a resist film on the protective film and then performing exposure and development to form a resist pattern, in which the method is used for manufacturing a semiconductor.

[29] A method for manufacturing a semiconductor device, the method including: forming a protective film using the composition for forming a protective film according to any one of [1] to [16] on a semiconductor substrate having a surface on which an inorganic film is optionally formed, forming a resist pattern on the protective film, dry etching the protective film using the resist pattern as a mask to expose the inorganic film or the surface of the semiconductor substrate, and wet etching and cleaning the inorganic film or the semiconductor substrate using a wet etching solution for a semiconductor using the protective film after the dry etching as a mask.

[30] A method for manufacturing a semiconductor device, the method including: forming a resist underlayer film using the composition for forming a resist underlayer film according to any one of [18] to [25] on a semiconductor substrate having a surface on which an inorganic film is optionally formed, forming a resist pattern on the resist underlayer film, dry etching the resist underlayer film using the resist pattern as a mask to expose the inorganic film or the surface of the semiconductor substrate, and etching the inorganic film or the semiconductor substrate using the resist underlayer film after the dry etching as a mask.

### Advantageous Effects of Invention

According to the present invention, it is possible to provide a composition for forming a protective film that can form a protective film having excellent resistance to a wet etching solution for a semiconductor, and can also be effectively used as a composition for forming a resist underlayer film.

The composition for forming a protective film of the present invention is required to have, for example, the following characteristics with an excellent balance in a lithography process in manufacturing a semiconductor. The composition for forming a protective film has (1) an excellent mask function against a wet etching solution at the time of processing a base substrate, (2) a further reduction in damage to a protective film or a resist underlayer film at the time of processing a substrate by a low dry etching rate, (3) excellent planarization of a stepped substrate, and (4) excellent embeddability in a fine trench pattern substrate. The semiconductor substrate has the performances (1) to (4) in a well-balanced manner, and thus can be easily micro-processed.

### DESCRIPTION OF EMBODIMENTS

Hereinafter, the present invention will be described in detail. Note that the descriptions of the constituent elements described below are examples for describing the present invention, and the present invention is not limited to these contents.

### (Composition for Forming Protective Film Against Wet Etching Solution for Semiconductor)

A composition for forming a protective film against a wet etching solution for a semiconductor of the present invention contains:
(A) a compound or polymer having a reactive group capable of undergoing a crosslinking reaction in the presence of a curing agent;
(B) a curing agent;
(C) a compound having a hydroxy group and at least one of a hydroxy group and a carbonyl group; and
(D) a solvent.

The composition for forming a protective film of the present invention may further contain (E) a compound or polymer having a phenolic hydroxy group.

The present inventors have found that when a composition for forming a protective film containing (A) a compound or polymer having a reactive group capable of undergoing a crosslinking reaction in the presence of a curing agent, (B) a curing agent, and (D) a solvent further contains (C) a compound having a hydroxy group and at least one of a hydroxy group and a carbonyl group, a protective film having more excellent resistance to a wet etching solution for a semiconductor can be formed, thereby completing the present invention.

Although the reason why a protective film having more excellent resistance is formed is not clear, the present inventors consider that the resistance of the protective film to the wet etching solution for a semiconductor is further improved by a reaction (for example, chelation) of (C) the compound having a hydroxy group and at least one of a hydroxy group and a carbonyl group in the protective film with a protection target (for example, an inorganic film).

### <(A) Compound or Polymer>

The compound or polymer (A) used in the present invention is not particularly limited as long as it has a reactive group capable of undergoing a crosslinking reaction in the presence of a curing agent, and is appropriately selected according to the purpose. For example, the compound or polymer is preferably a compound or polymer containing a cyclic ether having a 3-membered ring structure or a 4-membered ring structure.

Here, examples of the cyclic ether having a 3-membered ring structure include an epoxy group. In addition, examples of the cyclic ether having a 4-membered ring structure include an oxetanyl group.

Examples of a more preferred embodiment of the compound or polymer (A) include a compound represented by the following first aspect and a polymer represented by the following second aspect.

### <<First Aspect>>

Examples of the compound (A) used in the present invention include the following compounds.

Such a compound (hereinafter, also referred to as a compound in the first aspect) is a compound that does not have a repeating structural unit,
the compound has a terminal group (A1), a polyvalent group (A2), and a linking group (A3),
the terminal group (A1) is bonded only to the linking group (A3),
the polyvalent group (A2) is bonded only to the linking group (A3),
the linking group (A3) is bonded on one hand to the terminal group (A1) and on the other hand to the polyvalent group (A2), and may optionally be bonded to another linking group (A3),
the terminal group (A1) has any of structures of the following Formula (I):

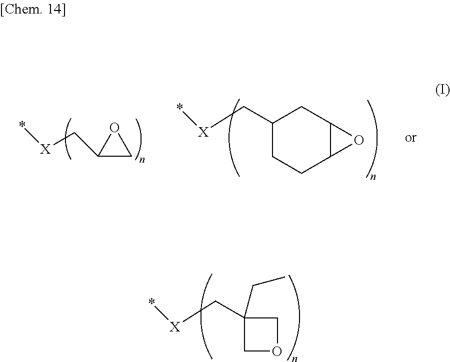

(in Formula (I), * represents a binding site to the linking group (A3), and
X represents an ether bond, an ester bond, or a nitrogen atom, in which n=1 when X is an ether bond or an ester bond, and n=2 when X is a nitrogen atom),
the polyvalent group (A2) is a divalent to tetravalent group selected from the group consisting of:
—O—;
an aliphatic hydrocarbon group;
a combination of an aromatic hydrocarbon group having fewer than 10 carbon atoms and an aliphatic hydrocarbon group; and
a combination of an aromatic hydrocarbon group having 10 or more carbon atoms and —O—, and
the linking group (A3) represents an aromatic hydrocarbon group.

The phrase “does not have a repeating structural unit” means to exclude a so-called polymer having a repeating structural unit, such as a polyolefin, a polyester, a polyamide, or a poly(meth)acrylate. A weight average molecular weight of the compound (A) is preferably 300 or more and 1,500 or less.

The “bond” between the terminal group (A1), the polyvalent group (A2), and the linking group (A3) means a chemical bond, and usually means a covalent bond, but does not preclude an ionic bond.

The polyvalent group (A2) is a divalent to tetravalent group.

Therefore, the aliphatic hydrocarbon group in the definition of the polyvalent group (A2) is a divalent to tetravalent aliphatic hydrocarbon group.

Non-limiting examples of the divalent aliphatic hydrocarbon group include alkylene groups such as a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

When hydrogen at an arbitrary site is removed from these groups and converted into a bond, trivalent and tetravalent groups are derived.

Examples of the aromatic hydrocarbon group having fewer than 10 carbon atoms in the definition of the polyvalent group (A2) include benzene, toluene, xylene, mesitylene, cumene, styrene, and indene.

Examples of the aliphatic hydrocarbon group that is combined with an aromatic hydrocarbon group having fewer than 10 carbon atoms include, in addition to the alkylene groups described above, alkyl groups such as a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, and a decyl group.

Any of the aromatic hydrocarbon group having fewer than 10 carbon atoms and the aliphatic hydrocarbon group in the definition of the polyvalent group (A2) may be bonded to the linking group (A3).

Examples of the aromatic hydrocarbon group having 10 or more carbon atoms in the definition of the polyvalent group (A2) include naphthalene, azulene, anthracene, phenanthrene, naphthacene, triphenylene, pyrene, and chrysene.

The aromatic hydrocarbon group having 10 or more carbon atoms in the definition of the polyvalent group (A2) is preferably bonded to the linking group (A3) via —O—.

Examples of the aromatic hydrocarbon group in the definition of the linking group (A3) include the aromatic hydrocarbon group having fewer than 10 carbon atoms and the aromatic hydrocarbon group having 10 or more carbon atoms.

Preferably, the compound (A) has two or more linking groups (A3).

The compound in the first aspect is preferably represented by, for example, the following Formula (II):

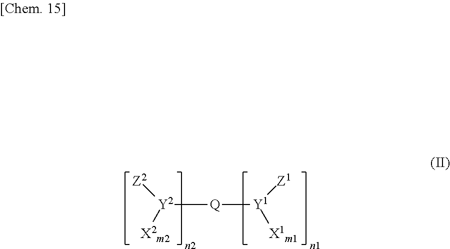

(in Formula (II),
Z¹ and Z² each independently represent

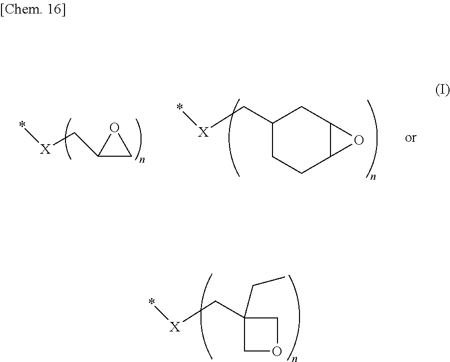

(in Formula (I), * represents Y¹ or a binding site to Y², and
X represents an ether bond, an ester bond, or a nitrogen atom, in which n=1 when X is an ether bond or an ester bond, and n=2 when X is a nitrogen atom),
Y¹ and Y² each independently represent an aromatic hydrocarbon group,
X¹ and X² each independently represent —Y¹—Z¹ or —Y²—Z²,
n1 and n2 each independently represent an integer from 0 to 4, where any one of n1 and n2 is 1 or more,
m1 defined in (X¹)m1 represents 0 or 1,
m2 defined in (X²)m2 represents 0 or 1, and
Q represents a (n1+n2)-valent group selected from the group consisting of —O—, an aliphatic hydrocarbon group, a combination of an aromatic hydrocarbon group having fewer than 10 carbon atoms and an aliphatic hydrocarbon group, and a combination of an aromatic hydrocarbon group having 10 or more carbon atoms and —O—), and
Q is preferably a divalent to tetravalent group.

In Formula (II), Z¹ and Z² correspond to the terminal group (A1), Q corresponds to the polyvalent group (A2), Y¹ and Y² correspond to the linking group (A3), and the description, examples, and the like thereof are as described above.

The compound in the first aspect preferably has a partial structure represented by, for example, the following Formula (III).

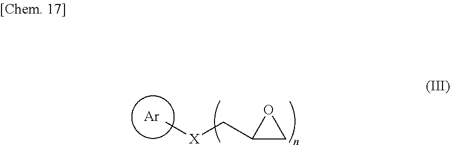

(In Formula (III), Ar represents a benzene ring, a naphthalene ring, or an anthracene ring, and X represents an ether bond, an ester bond, or a nitrogen atom, in which n=1 when X is an ether bond or an ester bond, and n=2 when X is a nitrogen atom).

Examples of the compound in the first aspect include the following compounds.

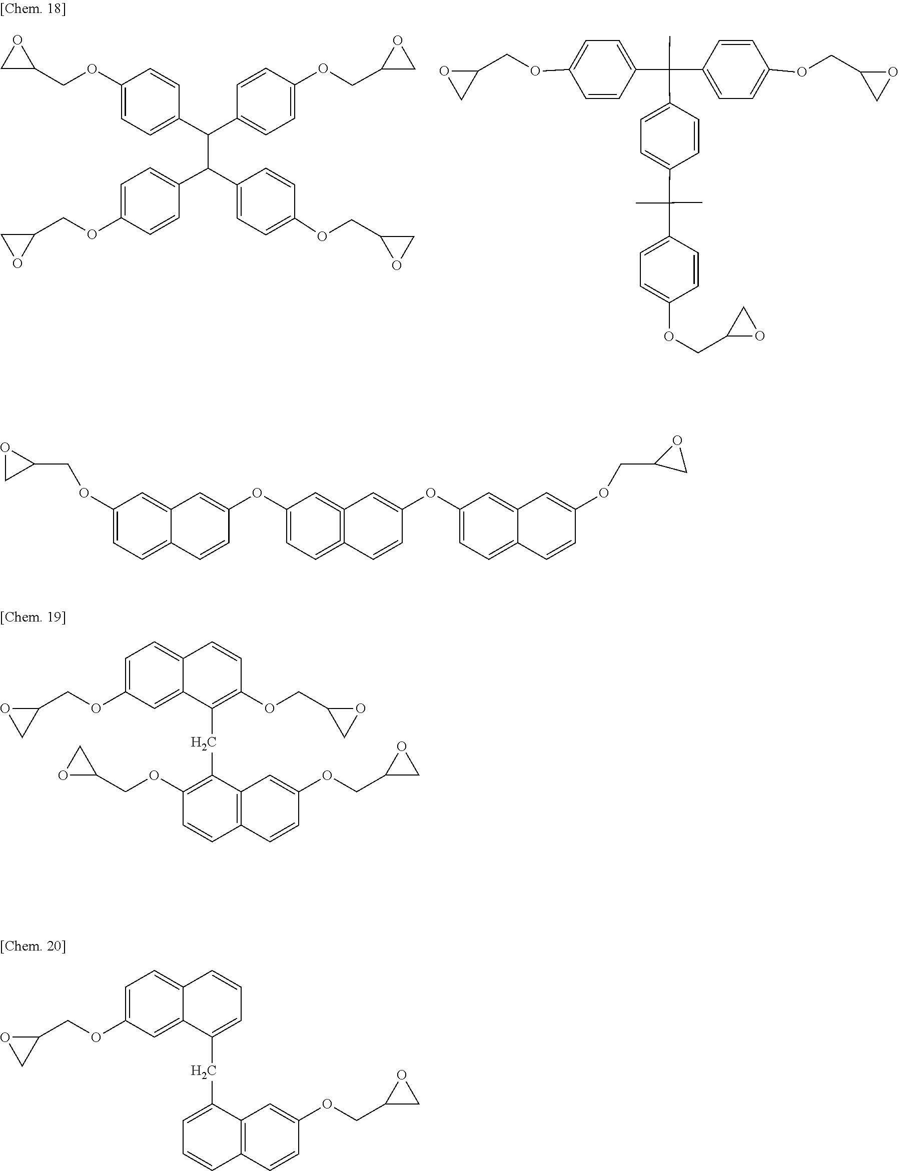

### <<Second Aspect>>

Examples of the polymer (A) used in the present invention include the following polymers.

Such a polymer (hereinafter, also referred to as a polymer in the second aspect) is a polymer having a unit structure represented by the following Formula (1-1):

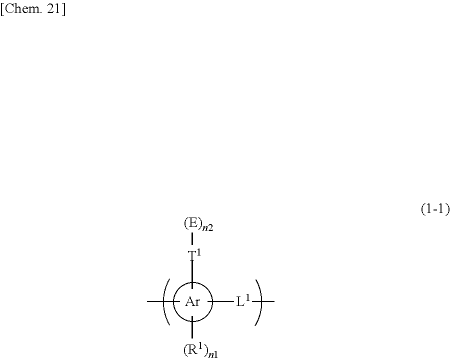

(in Formula (1-1), Ar represents a benzene ring, a naphthalene ring, or an anthracene ring, R¹ represents a hydroxy group, a mercapto group which may be protected by a methyl group, an amino group which may be protected by a methyl group, a halogeno group, or an alkyl group having 1 to 10 carbon atoms, which may be substituted with or interrupted by a heteroatom and may be substituted with a hydroxy group, n1 represents an integer from 0 to 3, L¹ represents a single bond or an alkylene group having 1 to 10 carbon atoms, n2 represents 1 or 2, E represents a group having an epoxy group or a group having an oxetanyl group, T¹ represents a single bond or an alkylene group having 1 to 10 carbon atoms, which may be interrupted by an ether bond, an ester bond, or an amide bond when n2=1, and T¹ represents a nitrogen atom or an amide bond when n2=2).

Examples of the alkyl group having 1 to 10 carbon atoms include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, a decyl group, a methoxy group, an ethoxy group, a methoxymethyl group, an ethoxymethyl group, a methoxyethyl group, an ethoxyethyl group, a hydroxymethyl group, a 1-hydroxyethyl group, a 2-hydroxyethyl group, a methylamino group, a dimethylamino group, a diethylamino group, an aminomethyl group, a 1-aminoethyl group, a 2-aminoethyl group, a methylthio group, an ethylthio group, a mercaptomethyl group, a 1-mercaptoethyl group, and a 2-mercaptoethyl group.

Examples of the alkylene group having 1 to 10 carbon atoms include a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

An example of the alkyl group having 1 to 10 carbon atoms which is substituted with or interrupted by a heteroatom in R¹ is an alkoxy group having 1 to 10 carbon atoms.

Examples of the alkoxy group having 1 to 10 carbon atoms include a methoxy group, an ethoxy group, an n-propoxy group, an i-propoxy group, an n-butoxy group, an i-butoxy group, an s-butoxy group, a t-butoxy group, an n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, an n-heptyloxy group, an n-octyloxy group, and an n-nonyloxy group.

The unit structure represented by Formula (1-1) may be one kind or a combination of two or more kinds. For example, a copolymer having a plurality of unit structures in which Ar is the same kind may be used, and for example, a copolymer having a plurality of unit structures in which Ar is different in kind, such as a copolymer having a unit structure in which Ar has a benzene ring and having a unit structure having a naphthalene ring, is not excluded from the technical scope of the present application.

The phrase “may be interrupted” means that in the case of an alkylene group having 2 to 10 carbon atoms, any carbon-carbon atom in the alkylene group is interrupted by a heteroatom (that is, an ether bond in the case of oxygen or a sulfide bond in the case of sulfur), an ester bond, or an amide bond, and means that in the case of a carbon atom number of 1 (that is, a methylene group), one of the carbons of the methylene group has a heteroatom (that is, an ether bond in the case of oxygen or a sulfide bond in the case of sulfur), an ester bond, or an amide bond.

T¹ represents a single bond, or an alkylene group having 1 to 10 carbon atoms, which may be interrupted by an ether bond, an ester bond, or an amide bond, when n2=1, and is preferably a combination of an ether bond and a methylene group (that is, when “-T¹-(E)n2” in Formula (1-1) is a glycidyl ether group), a combination of an ester bond and a methylene group, or a combination of an amide bond and a methylene group.

The alkyl group having 1 to 10 carbon atoms, which may be substituted with a heteroatom, means that one or more hydrogen atoms of the alkyl group having 1 to 10 carbon atoms are substituted with a heteroatom (preferably a halogeno group).

L¹ represents a single bond or an alkylene group having 1 to 10 carbon atoms, and is preferably represented by Formula (1-2):

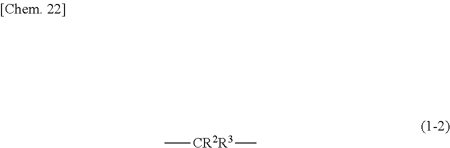

(in Formula (1-2), R² and R³ each independently represent a hydrogen atom, a methyl group, an ethyl group, an n-propyl group, an i-propyl group, a cyclopropyl group, an n-butyl group, an i-butyl group, an s-butyl group, a t-butyl group, or a cyclobutyl group, and R² and R³ may be bonded to each other to form a ring having 3 to 6 carbon atoms). Among them, both R² and R³ are preferably a hydrogen atom (that is, —(CR²R³)— is a methylene group).

The halogeno group refers to halogen-X (F, Cl, Br, or I) substituted with hydrogen.

E in Formula (1-1) is more preferably a group having an epoxy group.

The polymer in the second aspect is not particularly limited as long as it satisfies, for example, the unit structure of Formula (1-1). The polymer may be produced by a known method. Commercially available products may be used. Examples of the commercially available products include heat-resistant epoxy novolac resin EOCN (registered trademark) series (manufactured by Nippon Kayaku Co., Ltd.) and epoxy novolac resin D.E.N (registered trademark) series (manufactured by Dow Chemical Japan Ltd.).

A weight average molecular weight of the polymer in the second aspect is 100 or more, 500 to 200,000, 600 to 50,000, or 700 to 10,000.

Examples of the polymer in the second aspect include polymers having the following unit structure.

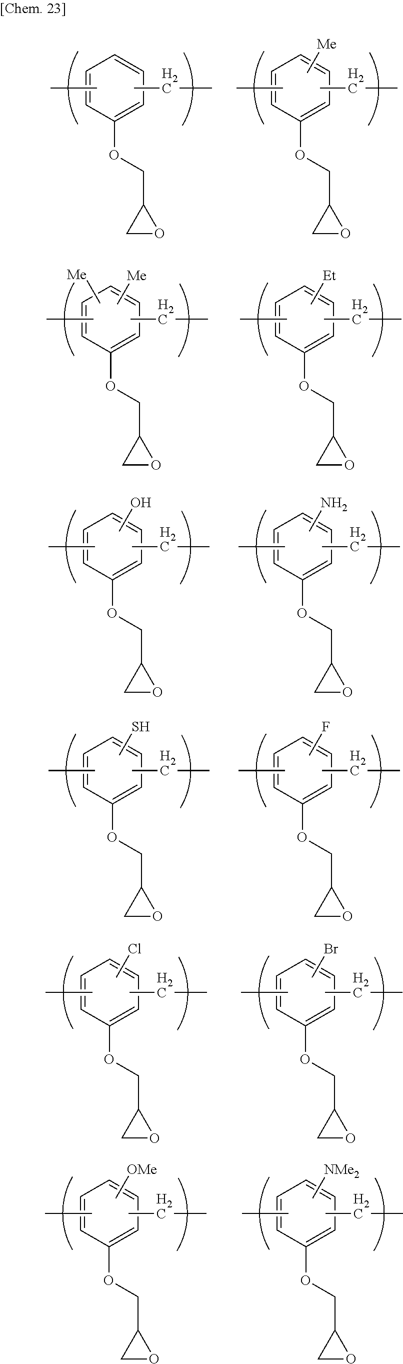

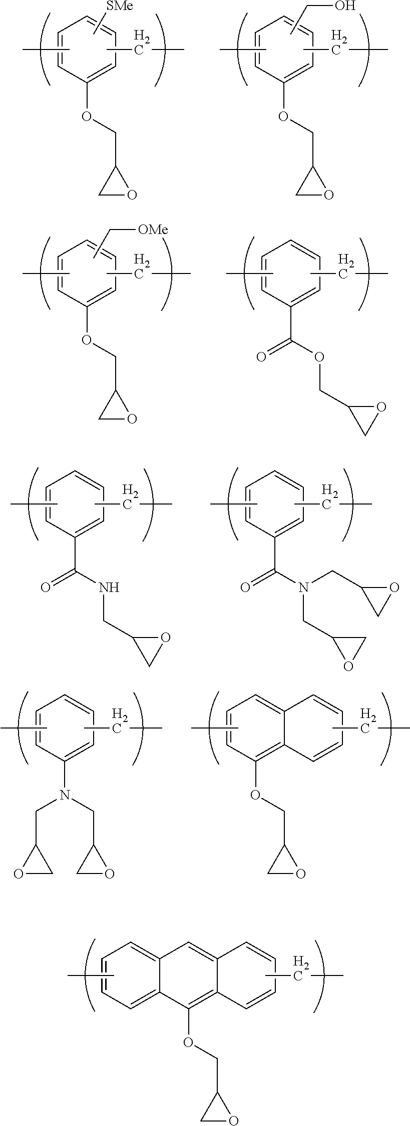

Me represents a methyl group, and Et represents an ethyl group.

### <(B) Curing Agent>

The component (B) used in the present invention is a curing agent.

The curing agent is not particularly limited as long as a reactive group capable of undergoing a crosslinking reaction of the component (A) can be undergone a crosslinking reaction, and examples thereof include a base, a thermal acid generator, a phenolic curing agent, an amide-based curing agent, an amine-based curing agent, imidazoles, an acid anhydride-based curing agent, organophosphines, a mercaptan-based curing agent, a tertiary amine, a phosphonium salt, a tetraphenylboron salt, an organic acid dihydrazide, a halogenated boroamine complex, an isocyanate-based curing agent, and a blocked isocyanate-based curing agent.

Note that, for example, 2-phenylimidazole is a base and also imidazoles. As described above, in the present invention, there may be specific examples belonging to a plurality of types of subordinate concepts of the curing agents exemplified above.

### <<Base>>

The present inventors have found that a composition for forming a protective film containing:
(A′) a compound or polymer having a reactive group capable of undergoing a crosslinking reaction in the presence of a base;
(B′) a base; and
(D) a solvent, is a composition for forming a protective film capable of forming a protective film having excellent resistance to a wet etching solution for a semiconductor, and is a composition that can be effectively used as a composition for forming a resist underlayer film (Japanese Patent Application No. 2021-183272 A and its priority application PCT/JP2022/37571). Note that the contents of Japanese Patent Application No. 2021-183272 A and PCT/JP2022/37571 are hereby incorporated in their entireties by reference, to the extent that they have been disclosed herein.

The present inventors have confirmed that even when the composition for forming a protective film further contains the compound having a hydroxy group and at least one of a hydroxy group and a carbonyl group (C), a protective film having more excellent resistance to a wet etching solution for a semiconductor can be formed.

Examples of the base include imidazole-based compounds (a piperidine compound, an amide-based compound, an amine-based compound, a diazabicycloundecene (DBU)-based compound, a diazabicyclononene (DBN)-based compound, a phosphonium-based compound, and a urea-based compound). Among them, an imidazole-based compound is preferable from the viewpoint of storage stability.

The base used in the present invention may also include an aspect constituting a salt with an acid.

For example, an imidazole-based compound will be described below as an example.

Examples of the base of the component (B) referred to in the present invention include (i) an imidazole-based compound represented by the following Formula (B1), (ii) a salt of an imidazole-based compound represented by Formula (B1) and an acid, and (iii) a quaternary salt containing a cation represented by the following Formula (B2).

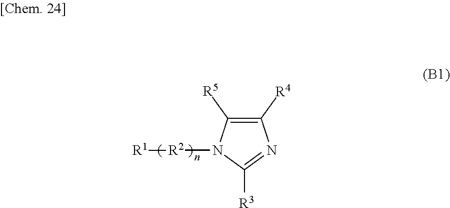

(In Formula (B1), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or fewer carbon atoms, which may be substituted, R⁵ represents a hydrogen atom, a formyl group, an alkyl group having 1 to 4 carbon atoms, which may be substituted, or an alkoxyalkyl group having 4 or fewer carbon atoms, which may be substituted, and n represents 0 or 1.)

Examples of the substituents in the aryl group which may be substituted and the triazine ring which may be substituted include an amino group and a hydroxy group.

The alkyl group may be linear or branched.

Examples of the aryl group include a phenyl group, a naphthyl group, a biphenyl group, and an anthryl group.

In R⁴ or R⁵, examples of the substituents in the alkyl group which may be substituted and the alkoxyalkyl group which may be substituted include a hydroxy group and a cyano group.

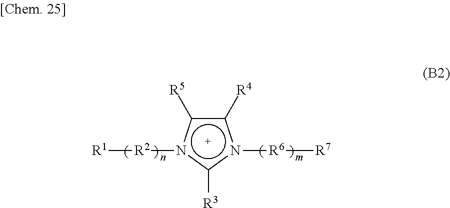

(In Formula (B2), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or fewer carbon atoms, which may be substituted, R⁵ represents a hydrogen atom, a formyl group, an alkyl group having 1 to 4 carbon atoms, which may be substituted, or an alkoxyalkyl group having 4 or fewer carbon atoms, which may be substituted, R⁶ represents an alkylene group having 1 to 4 carbon atoms, R⁷ represents an alkyl group having 1 to 4 carbon atoms or an aryl group which may be substituted, m represents 0 or 1, and n represents 0 or 1.)

In Formula (B2), the descriptions of R¹ to R⁵ are the same as in Formula (B1). In addition, in Formula (B2), examples of the substituent in the aryl group which may be substituted of R⁷ include an amino group and a hydroxy group. Specific examples of the aryl group of R⁷ include those described above.

In a case where the base of the component (B) referred to in the present invention forms a salt with a pair of anions as described above, the pair of anions are not particularly limited, and examples thereof include imide, halogen, carboxylate, sulfate, sulfonate, thiocyanate, aluminate, borate, phosphate, phosphinate, amide, antimonate, and methide, and more specifically include (CF₃SO₂)₂N⁻, (CF₃SO₂)(FSO₂)N⁻, (FSO₂)₂N⁻, (CF₃CF₂SO₂)₂N⁻, (CN)₂N⁻, OH⁻, Cl⁻, Br⁻, I⁻, NO₃⁻, CH₃COO⁻, CF₃COO⁻, CF₃CF₂CF₂COO⁻, CF₃SO₃⁻, CF₃CF₂SO₃⁻, CF₃CF₂CF₂CF₂SO₃⁻, SbF₆⁻, AlCl₄⁻, SCN⁻, PF₆⁻, BF₄⁻, [CF₃OCF₂CF₂BF₃⁻], and [(CₚF₂ₚ₊₁)BF₃]⁻ (p represents an integer of 1, 2, 3, or 4).

Further, examples thereof include anions represented by the following.

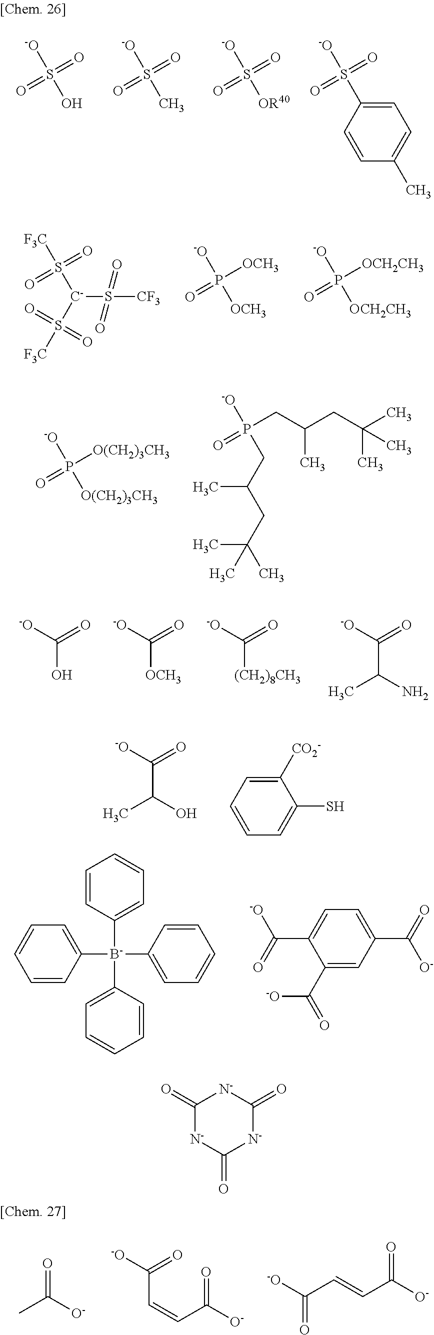

(In the formula, R⁴⁰ represents an alkyl group having 1 to 10 carbon atoms.)

The base used in the present invention is specifically shown below by taking an imidazole-based compound as an example, but is not limited thereto.

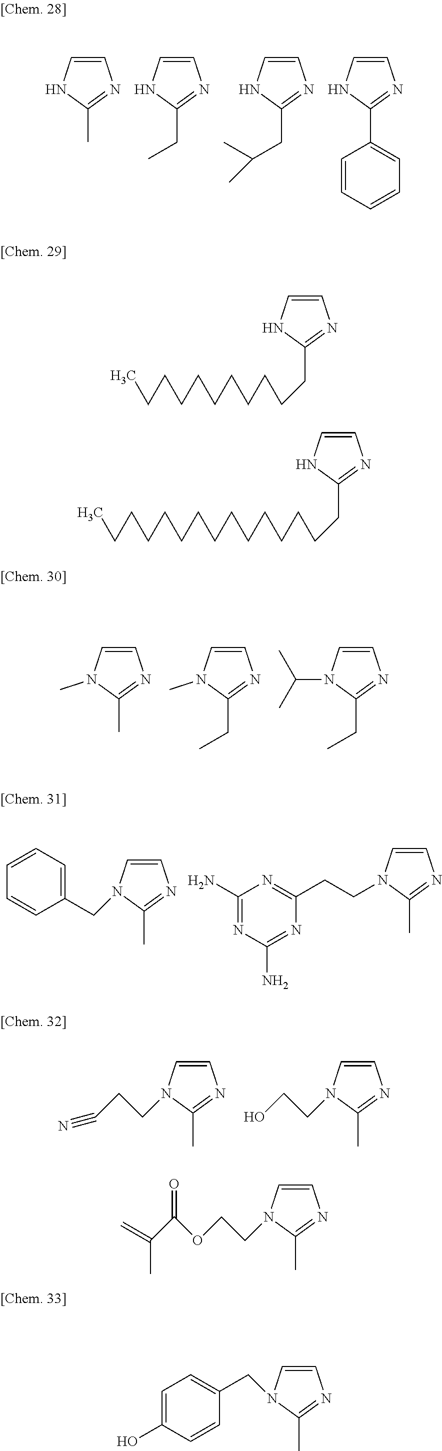

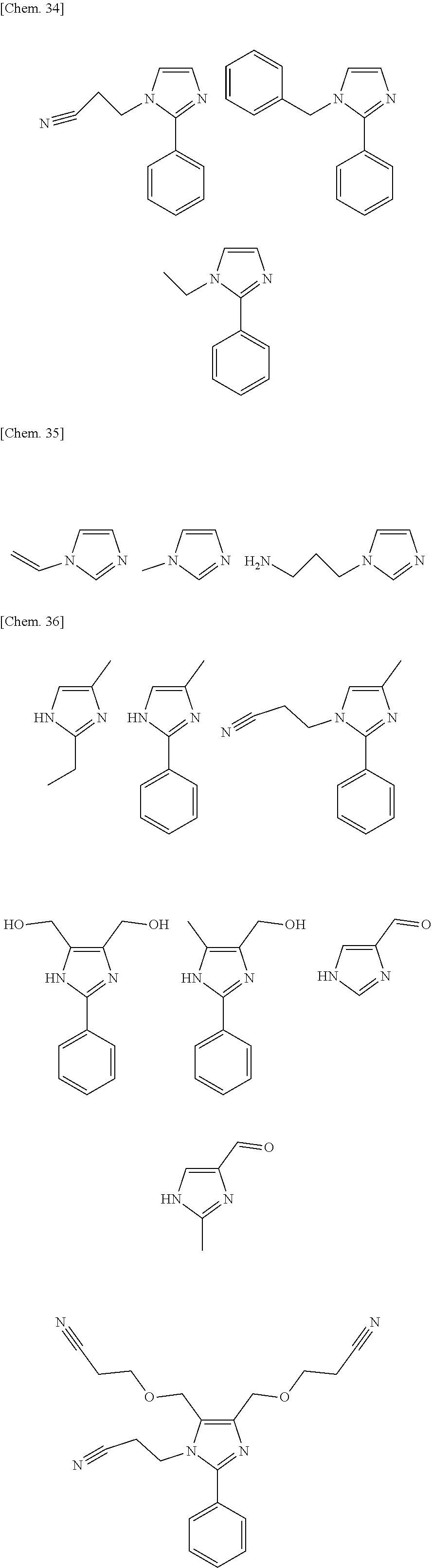

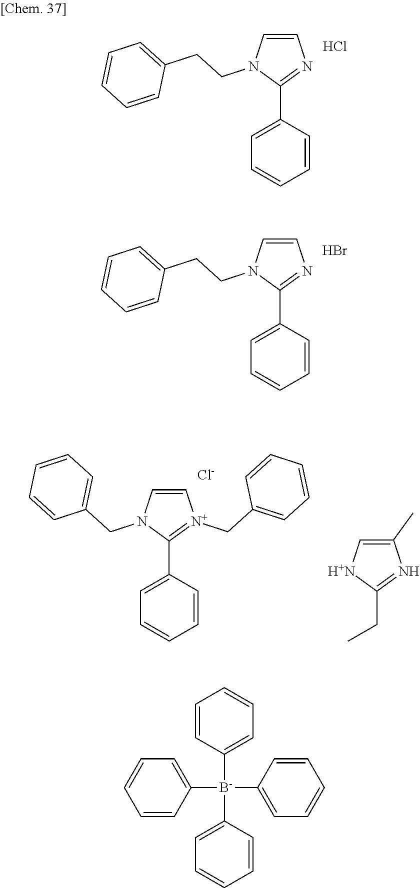

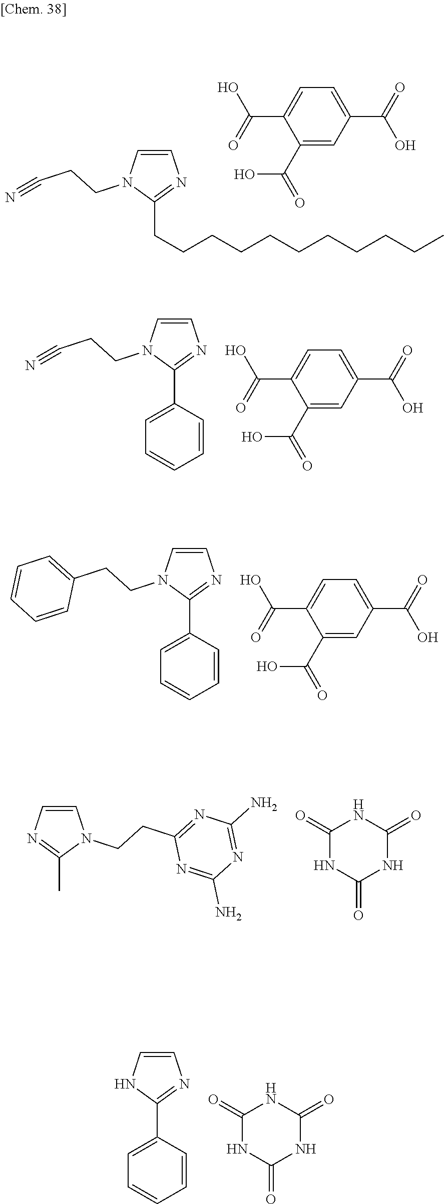

### <<Thermal Acid Generator>>

Examples of the thermal acid generator include pyridinium p-toluenesulfonate, pyridinium trifluoromethanesulfonate, pyridinium p-phenolsulfonate, K-PURE [registered trademark] CXC-1612, CXC-1614, TAG-2172, TAG-2179, TAG-2678, TAG2689 (manufactured by King Industries, Inc.), and SI-45, SI-60, SI-80, SI-100, SI-110, and SI-150 (manufactured by Sanshin Chemical Industry Co., Ltd.).

### <<Phenolic Curing Agent>>

Examples of the phenolic curing agent include bisphenol A, bisphenol F, 4,4′-dihydroxydiphenylmethane, 4,4′-dihydroxydiphenyl ether, 1,4-bis(4-hydroxyphenoxy)benzene, 1,3-bis(4-hydroxyphenoxy)benzene, 4,4′-dihydroxydiphenyl sulfide, 4,4′-dihydroxydiphenyl ketone, 4,4′-dihydroxydiphenyl sulfone, 4,4′-dihydroxybiphenyl, 2,2′-dihydroxybiphenyl, 10-(2,5-dihydroxyphenyl)-10H-9-oxa-10-phosphaphenanthrene-10-oxide, phenol novolac, bisphenol A novolac, o-cresol novolac, m-cresol novolac, p-cresol novolac, xylenol novolac, poly-p-hydroxystyrene, hydroquinone, resorcinol, catechol, t-butylcatechol, t-butylhydroquinone, fluoroglycinol, pyrogallol, t-butylpyrogallol, allylated pyrogallol, polyallylated pyrogallol, 1,2,4-benzenetriol, 2,3,4-trihydroxybenzophenone, 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,4-dihydroxynaphthalene, 2,5-dihydroxynaphthalene, 2,6-dihydroxynaphthalene, 2,7-dihydroxynaphthalene, 2,8-dihydroxynaphthalene, an allylated or polyallylated compound of the dihydroxynaphthalene, allylated bisphenol A, allylated bisphenol F, allylated phenol novolac, and allylated pyrogallol.

### <<Amine-Based Curing Agent>>

Examples of the amine-based curing agent include aliphatic amines, polyether amines, alicyclic amines, and aromatic amines.

Examples of the aliphatic amines include ethylenediamine, 1,3-diaminopropane, 1,4-diaminopropane, hexamethylenediamine, 2,5-dimethyl hexamethylenediamine, trimethylhexamethylenediamine, diethylenetriamine, iminobispropylamine, bis(hexamethylene)triamine, triethylenetetramine, tetraethylenepentamine, pentaethylenehexamine, N-hydroxyethyl ethylenediamine, and tetra(hydroxyethyl)ethylenediamine.

Examples of the polyether amines include triethylene glycol diamine, tetraethylene glycol diamine, diethylene glycol bis(propylamine), polyoxypropylene diamine, and polyoxypropylene triamines.

Examples of the alicyclic amines include isophoronediamine, methacenediamine, N-aminoethylpiperazine, bis(4-amino-3-methyldicyclohexyl)methane, bis(aminomethyl)cyclohexane, 3,9-bis(3-aminopropyl)-2,4,8,10-tetraoxaspiro(5,5)undecane, and norbornene diamine.

Examples of the aromatic amines include tetrachloro-p-xylenediamine, m-xylenediamine, p-xylenediamine, m-phenylenediamine, o-phenylenediamine, p-phenylenediamine, 2,4-diaminoanisole, 2,4-toluenediamine, 2,4-diaminodiphenylmethane, 4,4′-diaminodiphenylmethane, 4,4′-diamino-1,2-diphenylethane, 2,4-diaminodiphenylsulfone, 4,4′-diaminodiphenylsulfone, m-aminophenol, m-aminobenzylamine, benzyldimethylamine, 2-dimethylaminomethyl)phenol, triethanolamine, methylbenzylamine, α-(m-aminophenyl)ethylamine, α-(p-aminophenyl)ethylamine, diaminodiethyldimethyldiphenylmethane, and α,α′-bis(4-aminophenyl)-p-diisopropylbenzene.

### <<Imidazoles>>

Examples of the imidazoles include 2-phenylimidazole, 2-ethyl-4(5)-methylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-ethyl-4′-methylimidazolyl-(1′)]-ethyl-s-triazine, a 2,4-diamino-6-[2′-methylimidazolyl-(1′)]-ethyl-s-triazine isocyanuric acid adduct, a 2-phenylimidazole isocyanuric acid adduct, 2-phenyl-4,5-dihydroxymethylimidazole, 2-phenyl-4-methyl-5-hydroxymethylimidazole, and an adduct of the imidazoles with an epoxy resin.

### <<Acid Anhydride-Based Curing Agent>>

Examples of the acid anhydride-based curing agent include an acid anhydride and a modified product of an acid anhydride.

Examples of the acid anhydride include phthalic anhydride, trimellitic anhydride, pyromellitic anhydride, benzophenone tetracarboxylic anhydride, dodecenyl succinic anhydride, polyadipic anhydride, polyazelaic anhydride, polysebacic anhydride, poly(ethyl octadecanedioic acid) anhydride, poly(phenyl hexadecanedioic acid) anhydride, tetrahydrophthalic anhydride, methyltetrahydrophthalic anhydride, methylhexahydrophthalic anhydride, hexahydrophthalic anhydride, methylhymic anhydride, tetrahydrophthalic anhydride, trialkyltetrahydrophthalic anhydride, methylcyclohexene dicarboxylic anhydride, methylcyclohexene tetracarboxylic anhydride, ethylene glycol bistrimellitate dianhydride, HET anhydride, nadic anhydride, methylnadic anhydride, 5-(2,5-dioxotetrahydro-3-furanyl)-3-methyl-3-cyclohexane-1,2-dicarboxylic anhydride, 3,4-dicarboxy-1,2,3,4-tetrahydro-1-naphthalene succinic dianhydride, and 1-methyl-dicarboxy-1,2,3,4-tetrahydro-1-naphthalene succinic dianhydride.

Examples of the modified product of the acid anhydride include a product obtained by modifying the acid anhydride with a glycol. Here, examples of the glycol that can be used for modification include alkylene glycols such as ethylene glycol, propylene glycol, and neopentyl glycol, and polyether glycols such as polyethylene glycol, polypropylene glycol, and polytetramethylene ether glycol. Furthermore, copolymerized polyether glycols of two or more kinds of these glycols and/or polyether glycols can also be used. Note that, in the modified product of the acid anhydride, it is preferable to modify the acid anhydride in an amount of 0.4 mol or less of glycol with respect to 1 mol of the acid anhydride.

### <<Organophosphines>>

Examples of the organophosphines include tributylphosphine, methyldiphenylphosphine, triphenylphosphine, diphenylphosphine, and phenylphosphine.

### <<Phosphonium Salt>>

Examples of the phosphonium salt include tetraphenylphosphonium tetraphenylborate, tetraphenylphosphonium ethyltriphenylborate, and tetrabutylphosphonium tetrabutylborate.

### <<Tetraphenylboron Salt>>

Examples of the tetraphenylboron salt include 2-ethyl-4-methylimidazole tetraphenylborate and N-methylmorpholine tetraphenylborate.

As a content of the curing agent (B) in the composition for forming a protective film of the present invention, for example, a lower limit of the content thereof is usually 0.0001 mass %, preferably 0.01 mass %, and more preferably 0.1 mass %, with respect to the total solid content of the composition for forming a protective film, and an upper limit of the content thereof is usually 50 mass %, preferably 40 mass %, and more preferably 30 mass %, with respect to the total solid content of the composition for forming a protective film.

### <(C) Component>

The component (C) used in the present invention is a compound (hereinafter, referred to as a “(C) compound”) having a hydroxy group and at least one of a hydroxy group and a carbonyl group.

The number of carbon atoms of the compound (C) is, for example, 2 to 20.

As the compound (C), a compound represented by the following Formula (C-1), a compound represented by the following Formula (C-2), and a compound represented by the following Formula (C-3) are preferable.

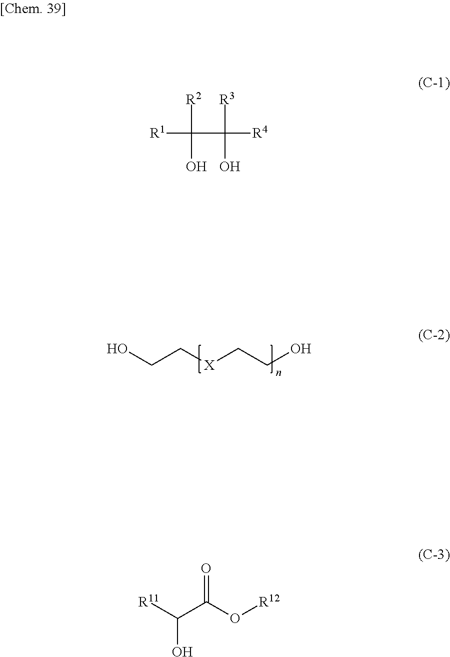

(In Formula (C-1), R¹ to R⁴ each independently represent a hydrogen atom, an alkyl group having 1 to 6 carbon atoms, or a hydroxyalkyl group having 1 to 6 carbon atoms,
in Formula (C-2), X represents —O— or —NR— (R represents a hydrogen atom, an alkyl group having 1 to 6 carbon atoms, which may have a hydroxy group, an aryl group having 6 to 12 carbon atoms, which may have a substituent, or an aralkyl group having 7 to 13 carbon atoms, which may have a substituent), n represents an integer from 1 to 3, and when n is 2 or 3, X may be the same or different, and
in Formula (C-3), R¹¹ represents an alkyl group having 1 to 4 carbon atoms, and R¹² represents an alkyl group having 1 to 6 carbon atoms).

The alkyl group and the hydroxyalkyl group in R¹ to R⁴ of Formula (C-1) may be linear, branched, or cyclic, and are preferably linear.

It is preferable that, in Formula (C-1), R¹ to R³ preferably represent a hydrogen atom, and R⁴ represents an alkyl group having 1 to 6 carbon atoms or a hydroxyalkyl group having 1 to 6 carbon atoms.

Examples of the aromatic ring in the aryl group having 6 to 12 carbon atoms, which may have a substituent, include a benzene ring and a naphthalene ring.

Examples of the aromatic ring in the aralkyl group having 7 to 13 carbon atoms, which may have a substituent, include a benzene ring and a naphthalene ring.

Examples of the substituents in the aryl group having 6 to 12 carbon atoms, which may have a substituent, and the aralkyl group having 7 to 13 carbon atoms, which may have a substituent, include an alkyl group having 1 to 6 carbon atoms and an alkoxy group having 1 to 6 carbon atoms.

R in —NR— of Formula (C-2) is preferably an alkyl group having 1 to 6 carbon atoms, which may have a hydroxy group, or an aryl group having 6 to 12 carbon atoms, which may have a substituent. As the alkyl group having 1 to 6 carbon atoms, which may have a hydroxy group, a hydroxyalkyl group is preferable, and a 2-hydroxyethyl group is more preferable.

In Formula (C-2), when X is —O—, n is preferably 2.

In Formula (C-2), when X is —NR—, n is preferably 1.

Examples of the compound (C) include the following compounds.

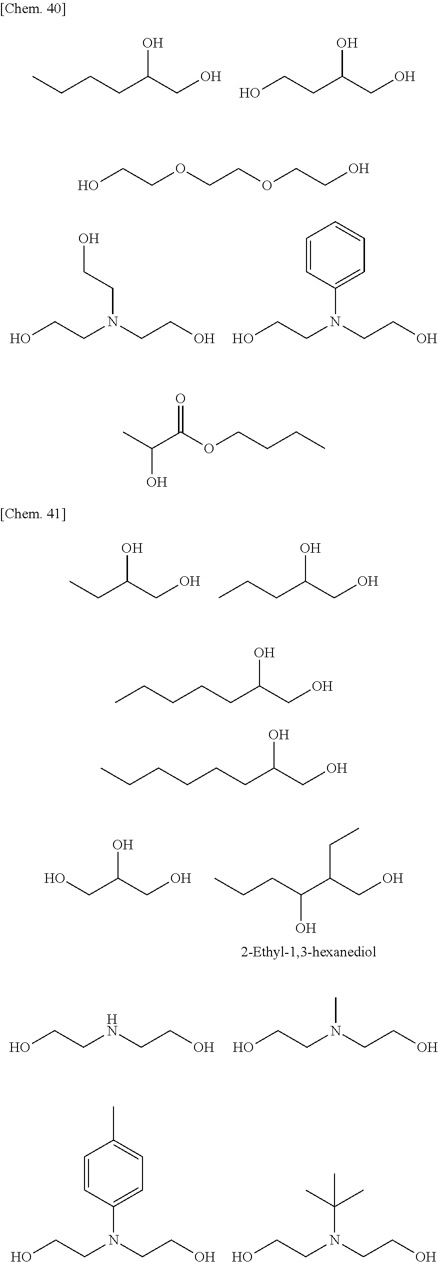

As a content of the compound (C) in the composition for forming a protective film of the present invention is not particularly limited, a lower limit of the content thereof is preferably 0.5 mass %, more preferably 1 mass %, and particularly preferably 5 mass %, with respect to the compound or polymer (A), and an upper limit of the content thereof is preferably 50 mass %, more preferably 30 mass %, and particularly preferably 20 mass %, with respect to the compound or polymer (A).

As a content of the compound (C) in the composition for forming a protective film of the present invention is not particularly limited, a lower limit of the content thereof is preferably 0.0001 mass %, more preferably 0.005 mass %, and particularly preferably 0.001 mass %, with respect to the solvent (D), and an upper limit of the content thereof is preferably 50 mass %, more preferably 30 mass %, and particularly preferably 20 mass %, with respect to the solvent (D).

### <(D) Solvent>

The composition for forming a protective film of the present invention can be prepared by dissolving the respective components described above in a solvent, preferably in an organic solvent, and is used in a uniform solution state. Note that, in the present invention, the solvent (D) is different from the compound (C).

The organic solvent for the composition for forming a protective film according to the present invention can be used without particular limitation as long as it is an organic solvent capable of dissolving solid components such as the compound or polymer (A), the curing agent (B), and other optional solid components. In particular, since the composition for forming a protective film according to the present invention is used in a uniform solution state, it is recommended to use an organic solvent generally used in a lithography process in combination in consideration of application performance thereof.

Examples of the organic solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monoethyl ether, propylene glycol monomethyl ether, propylene glycol monomethyl ether acetate, propropylene glycol propyl ether acetate, toluene, xylene, methyl ethyl ketone, methyl isobutyl ketone, cyclopentanone, cyclohexanone, cycloheptanone, 4-methyl-2-pentanol, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, 2-heptanone, methoxycyclopentane, anisole, γ-butyrolactone, N-methylpyrrolidone, N,N-dimethylformamide, and N,N-dimethylacetamide. These solvents can be used alone or in combination of two or more kinds thereof.

Among these solvents, propylene glycol monomethyl ether, propylene glycol monomethyl ether acetate, cyclohexanone, and the like are preferable. In particular, propylene glycol monomethyl ether and propylene glycol monomethyl ether acetate are preferable.

A solid content of the composition for forming a protective film according to the present invention is usually 0.1 to 70 mass %, and preferably 0.1 to 60 mass %. The solid content is a content ratio of all components excluding the solvent from the composition for forming a protective film. A ratio of the compound or polymer (A) in the solid content is preferably 1 to 100 mass %, more preferably 1 to 99.9 mass %, still more preferably 50 to 99.9 mass %, further still more preferably 50 to 95 mass %, and particularly preferably 50 to 90 mass %.

### <(E) Compound or Polymer Having Phenolic Hydroxy Group>

The composition for forming a protective film of the present invention may further contain (E) a compound or polymer having a phenolic hydroxy group.

The compound or polymer having a phenolic hydroxy group (E) is not particularly limited as long as it is a compound or polymer that does not impair the effect of the present invention. Needless to say, the compound or polymer having a phenolic hydroxy group (E) is different from the compound or polymer (A).

A weight average molecular weight of the compound or polymer having a phenolic hydroxy group (E) (hereinafter, also referred to as (E) a compound or polymer) is also not particularly limited, and is, for example, 300 to 50,000.

The compound or polymer (E) preferably has two or more phenolic hydroxy groups.

More preferred embodiments of the compound or polymer (E) include, for example, compounds or polymers shown in the following third to fifth aspects.

### <<Third Aspect>>

Examples of the compound or polymer (E) used in the present invention include a compound or polymer represented by Formula (2-1).

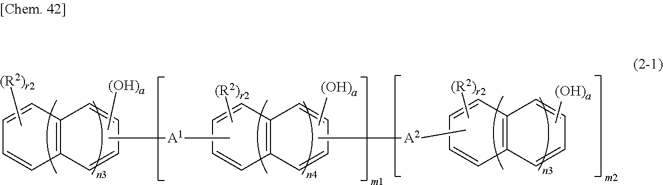

(In Formula (2-1), R²'s each independently represent a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, A¹ and A² each independently represent an alkylene group having 1 to 10 carbon atoms, a divalent organic group derived from a bicyclo ring compound, a biphenylene group, a divalent organic group represented by —C(T²)(T³)-, or a combination thereof, T² represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, and T³ represents a hydrogen atom or a monovalent group represented by Formula (2-1-a).)

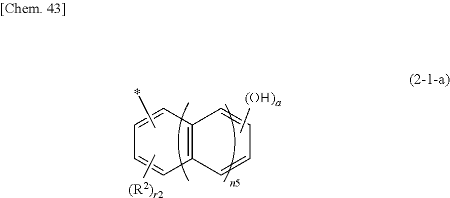

(* in Formula (2-1-a) represents a binding site to a carbon atom to which T³ is bonded, R² has the same meaning as R² in (Formula 2-1). a represents an integer from 1 to 6, n3 to n5 each independently represent an integer from 0 to 2, r2 represents an integer from 0 to 3, and m1 and m2 each independently represent 0 to 10,000,000.)

It is preferable that m1, n3 to n5, and r2 are 0, and m2 is 1.

The descriptions of the halogeno group, the alkoxy group, and the alkyl group according to Formula (2-1) are as described above.

Examples of the bicyclo ring compound include dicyclopentadiene, substituted dicyclopentadiene, tetracyclo[4.4.0.12,5.17,10]dodeca-3,8-diene, and substituted tetracyclo[4.4.0.12,5.17,10]dodeca-3,8-diene. Substitution means that one or two or more hydrogen atoms of the bicyclo ring compound are each independently substituted with a halogeno group, a nitro group, an amino group or a hydroxy group, or an alkyl group having 1 to 10 carbon atoms or an aryl group having 6 to 40 carbon atoms, which may be substituted with these groups. The divalent organic group derived from the bicyclo ring compound refers to a group having two bonds which is derived by removing any two hydrogen atoms from the bicyclo ring compound.

Examples of the aryl group having 6 to 40 carbon atoms include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an α-naphthyl group, a β-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Specific examples of the compound represented by Formula (2-1) include the following compounds.

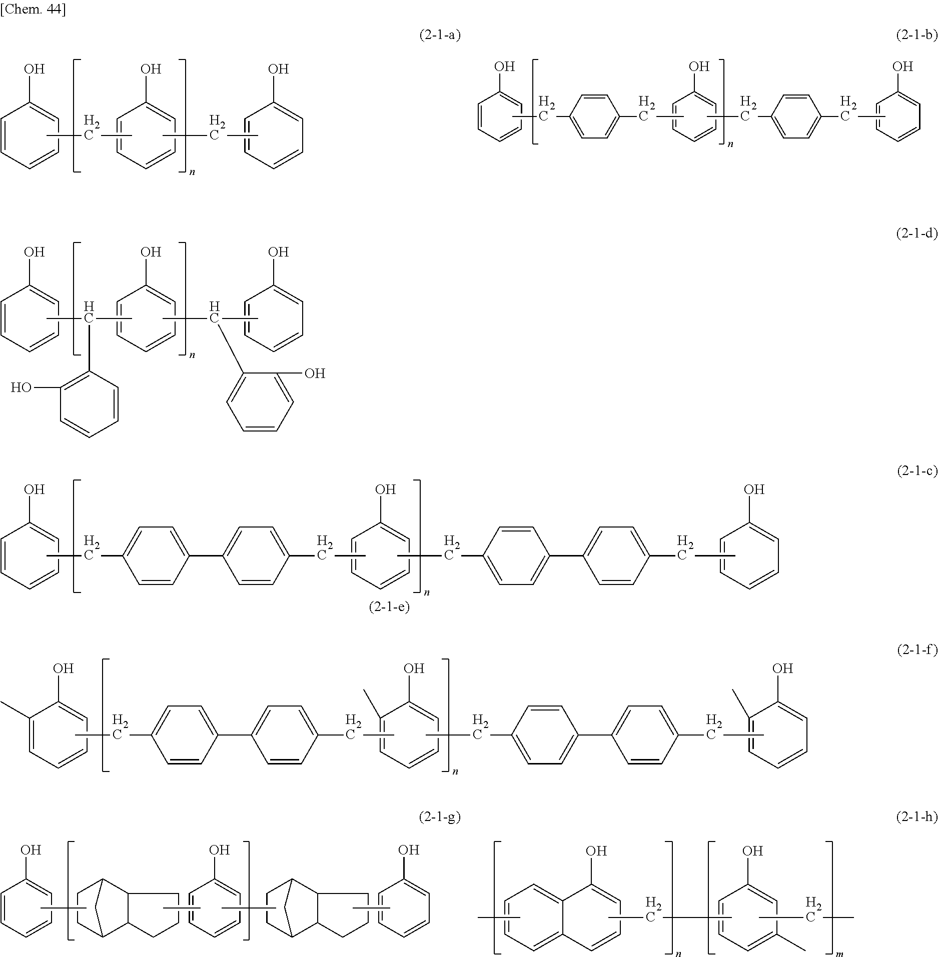

The compound or polymer (E) may be a compound shown below.

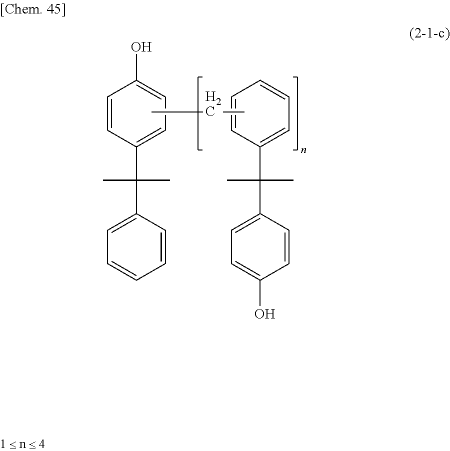

### <<Fourth Aspect>>

Examples of the compound or polymer (E) used in the present invention include a compound represented by Formula (2-2).

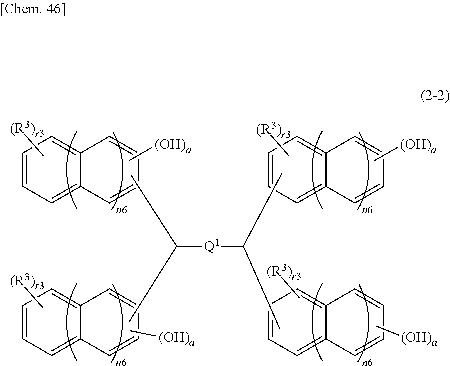

(In Formula (2-2), R³ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, Q¹ represents a single bond, an oxygen atom, a sulfur atom, a sulfonyl group, a carbonyl group, an imino group, an arylene group having 6 to 40 carbon atoms, or an alkylene group having 1 to 10 carbon atoms, which may be substituted with a halogeno group, a represents an integer from 1 to 6, n6 represents an integer from 0 to 2, and r3 represents an integer from 0 to 3).

The descriptions of the alkoxy group, the alkyl group, and the halogeno group of Formula (2-2) are as described above.

Examples of the arylene group having 6 to 40 carbon atoms include a phenylene group, an o-methylphenylene group, an m-methylphenylene group, a p-methylphenylene group, an o-chlorophenylene group, an m-chlorophenylene group, a p-chlorophenylene group, an o-chlorophenylene group, a p-fluorophenylene group, an o-methoxyphenylene group, a p-methoxyphenylene group, a p-nitrophenylene group, a p-cyanophenylene group, an α-naphthylene group, a β-naphthylene group, an o-biphenylylene group, an m-biphenylylene group, a p-biphenylylene group, a 1-anthrylene group, a 2-anthrylene group, a 9-anthrylene group, a 1-phenanthrylene group, a 2-phenanthrylene group, a 3-phenanthrylene group, a 4-phenanthrylene group, and a 9-phenanthrylene group.

Examples of the alkylene group having 1 to 10 carbon atoms include a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

Specific examples of the compound represented by Formula (2-2) include the following compounds.

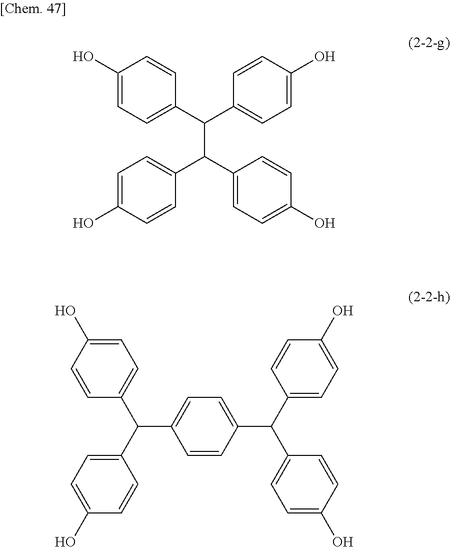 [SMILES: Oc1ccc(C(c2ccc(O)cc2)C(c2ccc(O)cc2)c2ccc(O)cc2)cc1 ; Oc1ccc(C(c2ccc(O)cc2)c2ccc(C(c3ccc(O)cc3)c3ccc(O)cc3)cc2)cc1]

The compound (E) may be a compound represented by the following Formula (4-1).

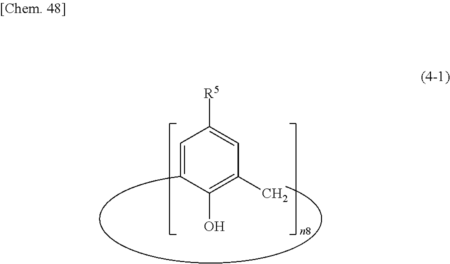

(In Formula (4-1), R⁵ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, and in the formula, n8 represents an integer of 4, 5, 6, or 8.)

The descriptions of the terms are as described above.

Specific examples of the compound represented by Formula (4-1) are shown below.

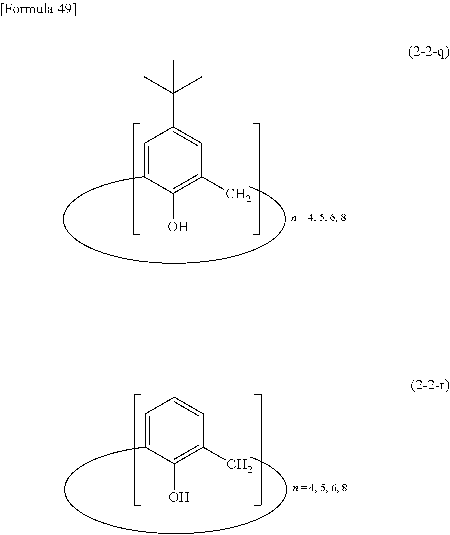

The compound (E) may be compounds represented by the following Formulas (5-1) and (5-1-a).

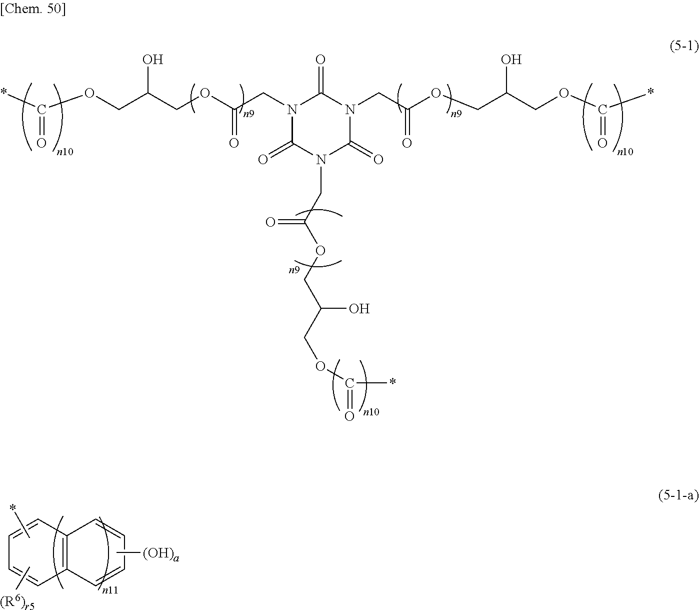

(In the formula, n9 and n10 each represent an integer of 0 or 1, R⁶ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, a represents an integer from 1 to 6, n11 represents an integer of 1 or 2, r5 represents an integer from 0 to 3, and * represents a binding site between the structure represented by Formula (5-1) and the structure represented by Formula (5-1-a).)

The descriptions of the terms are as described above.

Specific examples of the compounds represented by Formula (5-1) and Formula (5-1-a) are shown below.

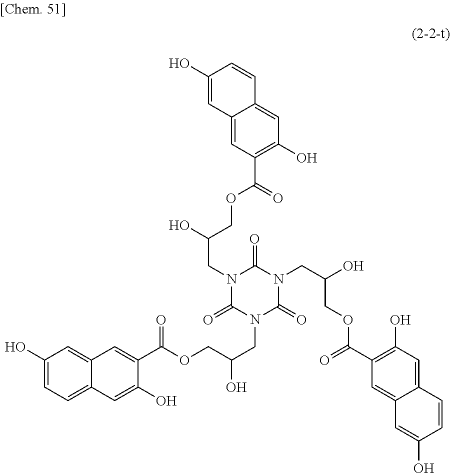 [SMILES: O=C(OCC(O)Cn1c(=O)n(CC(O)COC(=O)c2cc3cc(O)ccc3cc2O)c(=O)n(CC(O)COC(=O)c2cc3cc(O)ccc3cc2O)c1=O)c1cc2cc(O)ccc2cc1O]

The compound (E) may be a compound shown below.

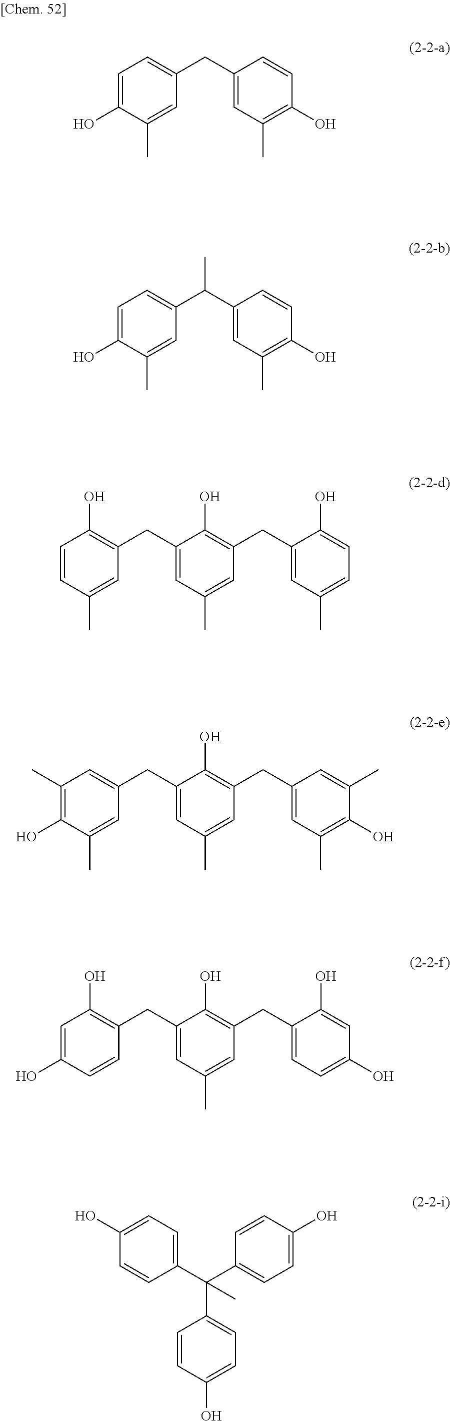 [SMILES: Cc1cc(Cc2ccc(O)c(C)c2)ccc1O ; Cc1cc(C(C)c2ccc(O)c(C)c2)ccc1O ; Cc1ccc(O)c(Cc2cc(C)cc(Cc3cc(C)ccc3O)c2O)c1 ; Cc1cc(Cc2cc(C)c(O)c(C)c2)c(O)c(Cc2cc(C)c(O)c(C)c2)c1 ; Cc1cc(Cc2ccc(O)cc2O)c(O)c(Cc2ccc(O)cc2O)c1 ; CC(c1ccc(O)cc1)(c1ccc(O)cc1)c1ccc(O)cc1]

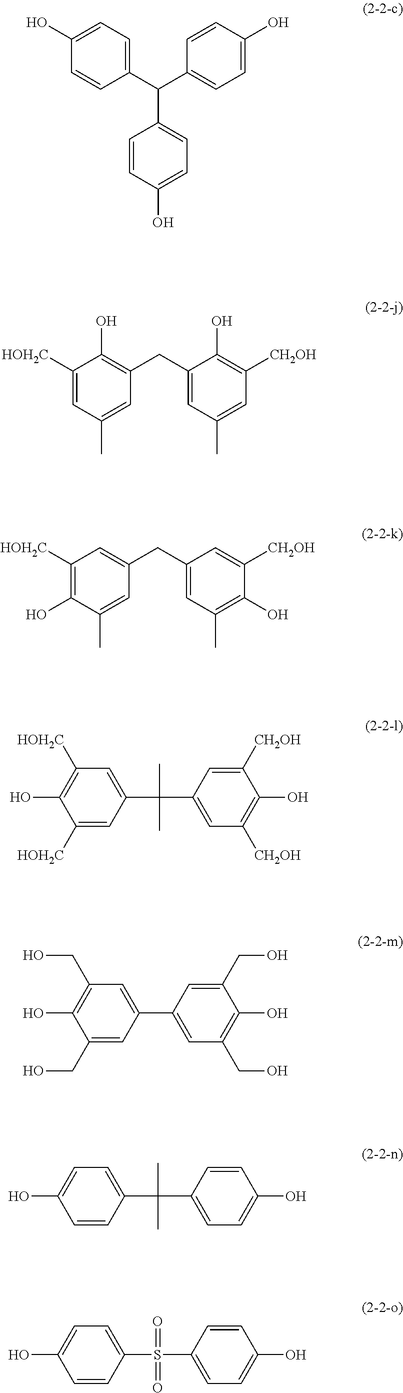

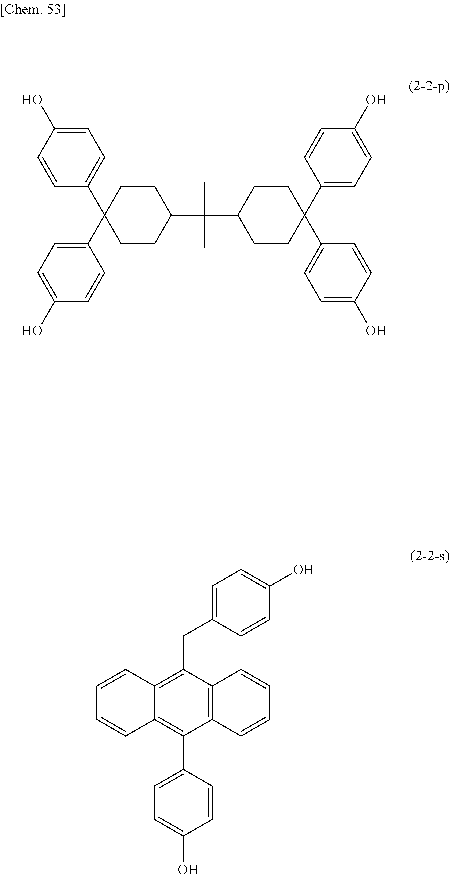 [SMILES: CC(C)(C1CCC(c2ccc(O)cc2)(c2ccc(O)cc2)CC1)C1CCC(c2ccc(O)cc2)(c2ccc(O)cc2)CC1 ; Oc1ccc(Cc2c3ccccc3c(-c3ccc(O)cc3)c3ccccc23)cc1]

### <<Fifth Aspect>>

The compound or polymer (E) used in the present invention is not particularly limited as long as it is a polymer that does not impair the effect of the present invention, and for example, the polymer (E) preferably has at least three or more repeating unit structures.

A weight average molecular weight of the polymer (E) is not particularly limited, and is, for example, 1,000 to 50,000.

The polymer (E) preferably has a unit structure represented by the following (Formula 3-1).

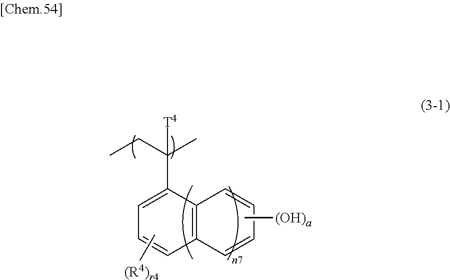

(In Formula (3-1), T⁴ represents a hydrogen atom or an alkyl group having 1 to 10 carbon atoms, which may be substituted with a halogeno group, R⁴ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, r4 represents an integer from 0 to 3, n7 represents an integer from 0 to 2, and a represents an integer from 1 to 6).

The descriptions of the halogeno group, the alkyl group, and the alkoxy group are as described above.

The polymer represented by Formula (3-1) may be a polymer having one kind of unit structure represented by Formula (3-1), or a copolymer having two or more kinds of unit structures represented by Formula (3-1).

Specific examples of the polymer (E) represented by Formula (3-1) include polymers having unit structures described below.

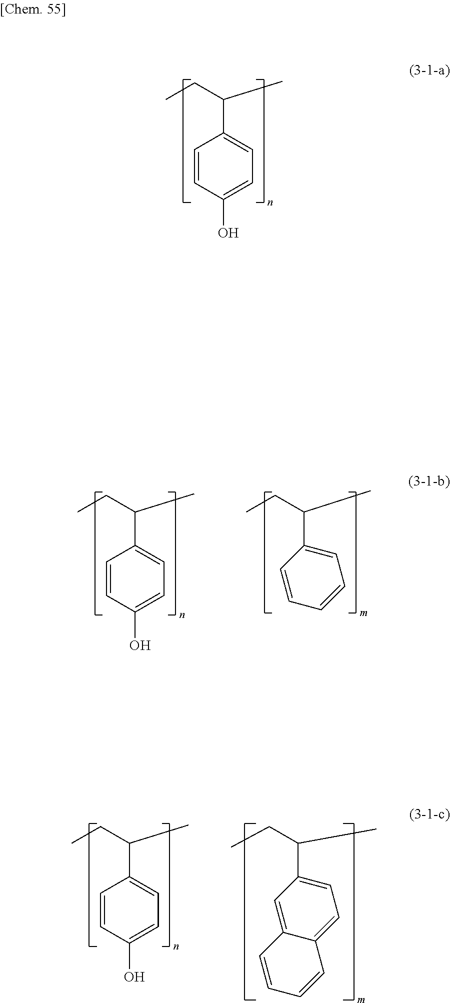

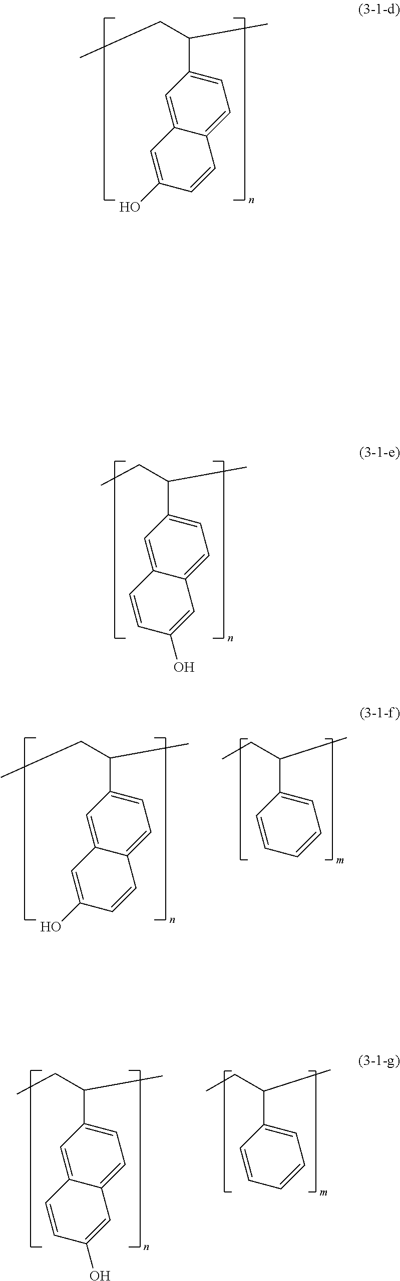

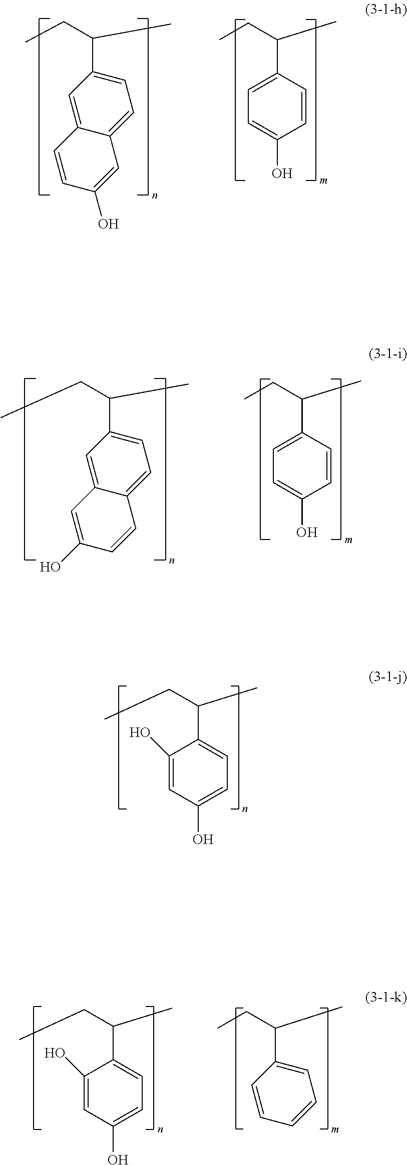

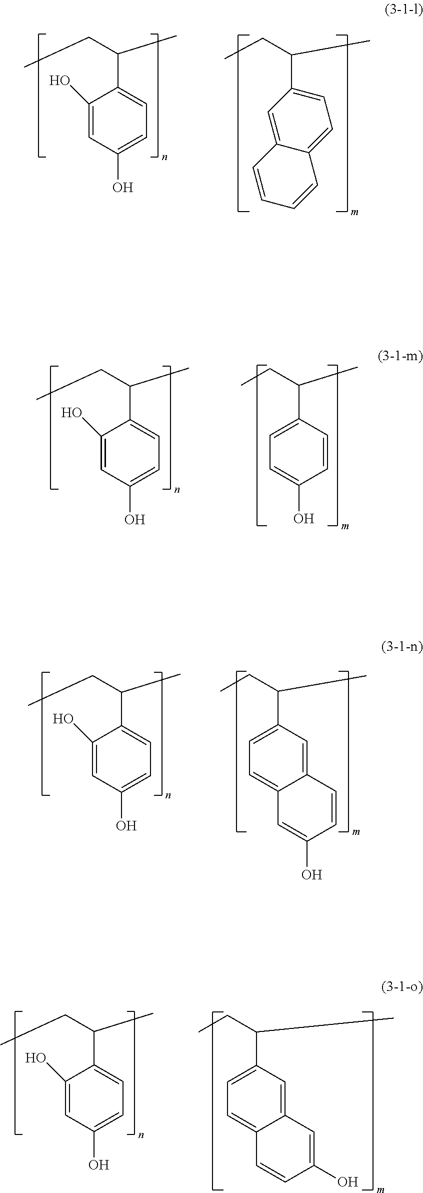

(In the above formula, m and n described beside the repeating unit represent a molar ratio of copolymerization.)

### (Composition for Forming Resist Underlayer Film)

A composition for forming a resist underlayer film of the present invention contains:
(A) a compound or polymer having a reactive group capable of undergoing a crosslinking reaction in the presence of a curing agent;
(B) a curing agent;
(C) a compound having a hydroxy group and at least one of a hydroxy group and a carbonyl group; and
(D) a solvent.

The composition for forming a protective film of the present invention described above not only can exhibit excellent resistance to a wet etching solution for a semiconductor but also can be effectively used as a composition for forming a resist underlayer film.

The descriptions of the terms related to the composition for forming a resist underlayer film of the present invention are the same as the description contents of the composition for forming a protective film.

(Protective Film, Resist Underlayer Film, Substrate with Resist Pattern, Method for Manufacturing Semiconductor Device, and the Like)

Hereinafter, a method for manufacturing a substrate with a resist pattern and a method for manufacturing a semiconductor device using the composition for forming a protective film (the composition for forming a resist underlayer film) according to the present invention will be described.

The protective film of the present invention is a baked product of a coating film formed of the composition for forming a protective film of the present invention.

The resist underlayer film of the present invention is a baked product of a coating film formed of the composition for forming a resist underlayer film of the present invention.

A method for manufacturing a substrate with a protective film of the present invention includes applying the composition for forming a protective film of the present invention onto a stepped semiconductor substrate and baking the composition to form a protective film. The method for manufacturing a substrate with a protective film is used for manufacturing a semiconductor.

A method for manufacturing a substrate with a resist pattern of the present invention includes applying the composition for forming a protective film of the present invention or the composition for forming a resist underlayer film of the present invention onto a semiconductor substrate and baking the composition to form a protective film as a resist underlayer film; and forming a resist film on the protective film and then performing exposure and development to form a resist pattern. The method for manufacturing a substrate with a resist pattern is used for manufacturing a semiconductor.

An embodiment of a method for manufacturing a semiconductor device of the present invention includes forming a protective film using the composition for forming a protective film of the present invention on a semiconductor substrate having a surface on which an inorganic film is optionally formed, forming a resist pattern on the protective film, dry etching the protective film using the resist pattern as a mask to expose the inorganic film or the surface of the semiconductor substrate, and wet etching and cleaning the inorganic film or the semiconductor substrate using a wet etching solution for a semiconductor using the protective film after the dry etching as a mask.

An embodiment of the method for manufacturing a semiconductor device of the present invention includes forming a resist underlayer film using the composition for forming a resist underlayer film of the present invention on a semiconductor substrate having a surface on which an inorganic film is optionally formed, forming a resist pattern on the resist underlayer film, dry etching the resist underlayer film using the resist pattern as a mask to expose the inorganic film or the surface of the semiconductor substrate, and etching the inorganic film or the semiconductor substrate using the resist underlayer film after the dry etching as a mask.

The substrate with a resist pattern according to the present invention can be manufactured by applying the composition for forming a protective film (the composition for forming a resist underlayer film) described above onto a semiconductor substrate and baking the composition.

Examples of the semiconductor substrate onto which the composition for forming a protective film (the composition for forming a resist underlayer film) of the present invention is applied include a silicon wafer, a germanium wafer, and a semiconductor wafer formed of a compound such as gallium arsenide, indium phosphide, gallium nitride, indium nitride, or aluminum nitride.

In a case where a semiconductor substrate having a surface on which an inorganic film is formed is used, the inorganic film is formed by, for example, an atomic layer deposition (ALD) method, a chemical vapor deposition (CVD) method, a reactive sputtering method, an ion-plating method, a vacuum deposition method, or a spin coating method (spin on glass: SOG). Examples of the inorganic film include a polysilicon film, a silicon oxide film, a silicon nitride film, a silicon oxynitride film, a Boro-Phospho Silicate Glass (BPSG) film, a titanium nitride film, a titanium oxynitride film, a tungsten nitride film, a gallium nitride film, and a gallium arsenide film. The semiconductor substrate may be a stepped substrate in which so-called vias (holes), trenches (grooves), and the like are formed. For example, the via has a substantially circular shape when viewed from an upper surface, a substantially circular diameter of the via is, for example, 2 nm to 20 nm, a depth of the via is 50 nm to 500 nm, a width of the groove (a recess of the substrate) of the trench is, for example, 2 nm to 20 nm, and a depth of the trench is 50 nm to 500 nm. Since the composition for forming a protective film (the composition for forming a resist underlayer film) of the present invention has a small weight average molecular weight and average particle size of the compound contained in the composition, the composition can be embedded even in the stepped substrate as described above without a defect such as a void. It is an important characteristic that there is no defect such as a void for a next step (wet etching/dry etching of the semiconductor substrate, or resist pattern formation) in manufacturing a semiconductor.

The composition for forming a protective film (the composition for forming a resist underlayer film) of the present invention is applied onto the semiconductor substrate by an appropriate coating method such as a spinner or a coater. Thereafter, baking is performed using heating means such as a hot plate to form a protective film (resist underlayer film). Conditions for baking are appropriately selected from a baking temperature of 100° C. to 400° C. and a baking time of 0.3 minutes to 60 minutes. Preferably, the baking temperature is 120° C. to 350° C. and the baking time is 0.5 minutes to 30 minutes, and more preferably, the baking temperature is 150° C. to 300° C. and the baking time is 0.8 minutes to 10 minutes. A thickness of the formed protective film is, for example, 0.001 μm to 10 μm, preferably 0.002 μm to 1 μm, and more preferably 0.005 μm to 0.5 μm. When the temperature during the baking is lower than the above range, the crosslinking may be insufficient, and the resistance of the formed protective film (resist underlayer film) to a resist solvent or a basic hydrogen peroxide aqueous solution may be hardly obtained. On the other hand, when the temperature during the baking is higher than the above range, the protective film (resist underlayer film) may be decomposed by heat.

A resist film is formed on the protective film formed as described above, and then exposed and developed to form a resist pattern.

The exposure is performed through a mask (reticle) for forming a predetermined pattern, and for example, an i-line, a KrF excimer laser, an ArF excimer laser, an extreme ultraviolet (EUV) ray, or an electron beam (EB) is used. An alkali developer is used in the development, and a development temperature and a development time are appropriately selected from 5° C. to 50° C. and 10 seconds to 300 seconds, respectively. As the alkali developer, for example, aqueous solutions of alkalis, for example, inorganic alkalis such as sodium hydroxide, potassium hydroxide, sodium carbonate, sodium silicate, sodium metasilicate, and ammonia water, primary amines such as ethylamine and n-propylamine, secondary amines such as diethylamine and di-n-butyl amine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, and cyclic amines such as pyrrole and piperidine, can be used. Furthermore, an appropriate amount of alcohols such as isopropyl alcohol and a surfactant such as a nonionic surfactant can be added to the aqueous solution of alkalis. Among them, a preferred developer is a quaternary ammonium salt and more preferably tetramethylammonium hydroxide or choline. Furthermore, a surfactant or the like can be added to the developer. Instead of the alkali developer, a method of performing development with an organic solvent such as butyl acetate and developing a portion where an alkali dissolution rate of the photoresist is not increased can also be used.

Next, the protective film (resist underlayer film) is dry-etched using the formed resist pattern as a mask. At this time, in a case where the inorganic film is formed on the surface of the semiconductor substrate used, when the inorganic film is not formed on the surface of the semiconductor substrate used by exposing the surface of the inorganic film, the surface of the semiconductor substrate is exposed.

Furthermore, a desired pattern is formed by wet etching using a wet etching solution for a semiconductor using the protective film (resist underlayer film) (also the resist pattern in a case where the resist pattern remains on the protective film/resist underlayer film) after dry etching as a mask.

As the wet etching solution for a semiconductor, a general chemical liquid for etching a semiconductor wafer can be used, and for example, both a substance exhibiting acidity and a substance exhibiting basicity can be used.

Examples of the substance exhibiting acidity include hydrogen peroxide, hydrofluoric acid, ammonium fluoride, acidic ammonium fluoride, ammonium hydrogen fluoride, buffered hydrofluoric acid, hydrochloric acid, nitric acid, sulfuric acid, phosphoric acid, and a mixed solution thereof.

Examples of the substance exhibiting basicity include basic hydrogen peroxide aqueous solutions obtained by mixing ammonia, sodium hydroxide, potassium hydroxide, sodium cyanide, potassium cyanide, or an organic amine such as triethanolamine with aqueous hydrogen peroxide, and adjusting a pH to a basic pH. Specific examples thereof include SC-1 (ammonia-hydrogen peroxide solution). In addition, a substance capable of adjusting a pH to a basic pH, for example, a substance capable of finally adjusting a pH to a basic pH by mixing urea with aqueous hydrogen peroxide and causing thermal decomposition of urea by heating to generate ammonia, can be used as a chemical liquid for wet etching.

Among them, aqueous acidic hydrogen peroxide or aqueous basic hydrogen peroxide is preferable.

These chemical liquids may contain an additive such as a surfactant.

The use temperature of the wet etching solution for a semiconductor is desirably 25° C. to 90° C. and more desirably 40° C. to 80° C. The wet etching time is desirably 0.5 minutes to 30 minutes and more desirably 1 minute to 20 minutes.

### EXAMPLES

Hereinafter, the content and effect of the present invention will be described in more detail with reference to Examples, but the present invention is not limited thereto.

The weight average molecular weight of the compound synthesized in the following Examples of the present specification is a measurement result by gel permeation chromatography (hereinafter, abbreviated as GPC). For the measurement, a GPC apparatus manufactured by Tosoh Corporation is used, and the measurement conditions and the like are as follows.

### GPC Column

Column temperature: 40° C.
Solvent: tetrahydrofuran (THF)
Flow rate: 1.0 ml/min
Standard sample: polystyrene (manufactured by Tosoh Corporation)

### Descriptions of Terms

PGME: propylene glycol monomethyl ether
PGMEA: propylene glycol monomethyl ether acetate

### Example 1

3.16 g (30 mass % PGMEA solution, weight average molecular weight: 3,100) of an epoxy novolac resin EOCN-104S (product manufactured by Nippon Kayaku Co., Ltd., corresponding to Formula (a-1)), 0.24 g of VP-2500 (product manufactured by Nippon Soda Co., Ltd., corresponding to Formula (a-3), weight average molecular weight: 3,687), 0.014 g of 1B2PZ (product manufactured by Shikoku Chemicals Corporation, corresponding to Formula (b-3)), 0.095 g of triethanolamine (Tokyo Chemical Industry Co., Ltd.), 0.0009 g of R-40-LM (DIC Corporation), 17.95 g of PGMEA, and 8.64 g of PGME were mixed, thereby obtaining a solution having a solid content of 4.0 mass %. The solution was filtered using a polytetrafluoroethylene microfilter having a pore size of 0.2 μm to prepare a composition for forming a protective film.

Note that the amount of triethanolamine relative to the epoxy novolac resin EOCN-104S is 10 mass %.

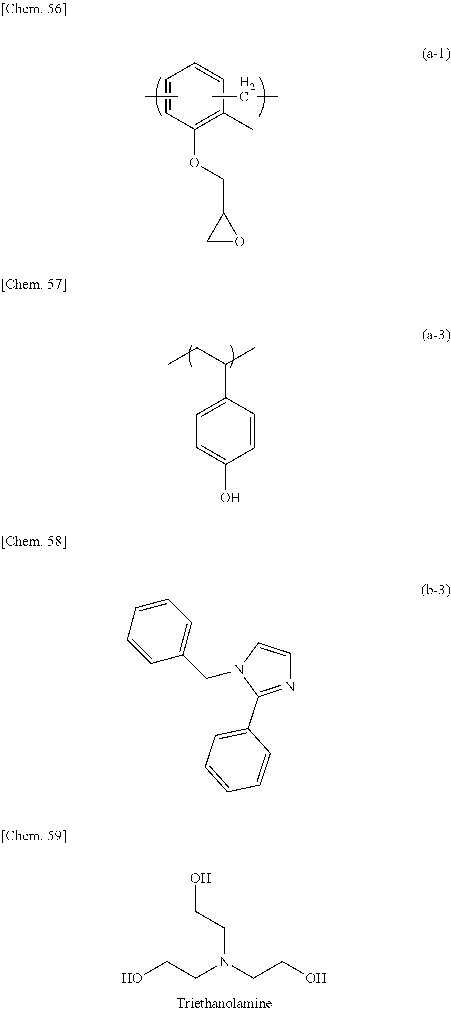

### Example 2

3.16 g (30 mass % PGMEA solution, weight average molecular weight: 3,100) of an epoxy novolac resin EOCN-104S (product manufactured by Nippon Kayaku Co., Ltd., corresponding to Formula (a-1)), 0.24 g of VP-2500 (product manufactured by Nippon Soda Co., Ltd., corresponding to Formula (a-3), weight average molecular weight: 3,687), 0.014 g of 1B2MZ (product manufactured by Shikoku Chemicals Corporation, corresponding to Formula (b-3)), 0.095 g of 1,2,4-butanetriol (Tokyo Chemical Industry Co., Ltd.), 0.0009 g of R-40-LM (DIC Corporation), 17.95 g of PGMEA, and 8.64 g of PGME were mixed, thereby obtaining a solution having a solid content of 4.0 mass %. The solution was filtered using a polytetrafluoroethylene microfilter having a pore size of 0.2 μm to prepare a composition for forming a protective film.

Note that the amount of 1,2,4-butanetriol relative to the epoxy novolac resin EOCN-104S is 10 mass %.

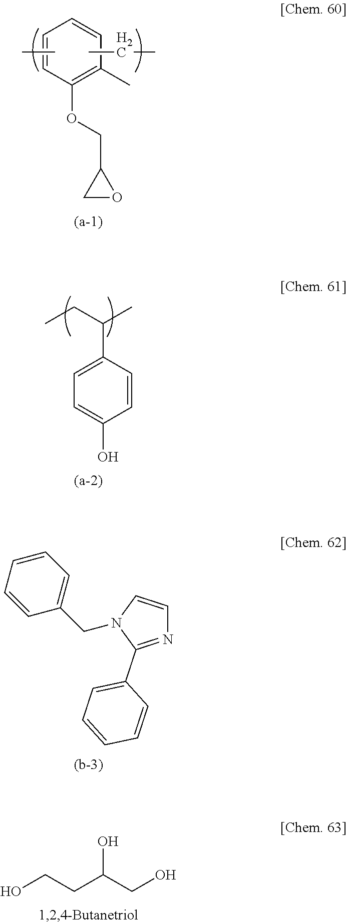

### Example 3

3.16 g (30 mass % PGMEA solution, weight average molecular weight: 3,100) of an epoxy novolac resin EOCN-104S (product manufactured by Nippon Kayaku Co., Ltd., corresponding to Formula (a-1)), 0.24 g of VP-2500 (product manufactured by Nippon Soda Co., Ltd., corresponding to Formula (a-3), weight average molecular weight: 3,687), 0.014 g of 1B2PZ (product manufactured by Shikoku Chemicals Corporation, corresponding to Formula (b-3)), 0.095 g of triethylene glycol (Tokyo Chemical Industry Co., Ltd.), 0.0009 g of R-40-LM (DIC Corporation), 17.95 g of PGMEA, and 8.64 g of PGME were mixed, thereby obtaining a solution having a solid content of 4.0 mass %. The solution was filtered using a polytetrafluoroethylene microfilter having a pore size of 0.2 μm to prepare a composition for forming a protective film.

Note that the amount of triethylene glycol relative to the epoxy novolac resin EOCN-104S is 10 mass %.

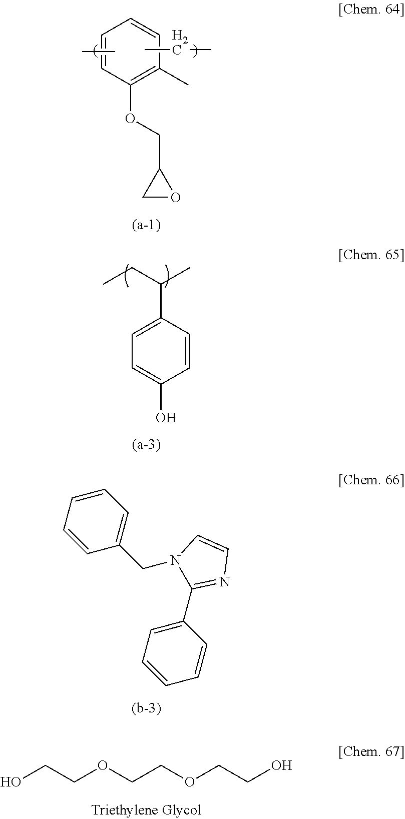

### Example 4

3.16 g (30 mass % PGMEA solution, weight average molecular weight: 3,100) of an epoxy novolac resin EOCN-104S (product manufactured by Nippon Kayaku Co., Ltd., corresponding to Formula (a-1)), 0.24 g of VP-2500 (product manufactured by Nippon Soda Co., Ltd., corresponding to Formula (a-3), weight average molecular weight: 3,687), 0.014 g of 1B2PZ (product manufactured by Shikoku Chemicals Corporation, corresponding to Formula (b-3)), 0.095 g of 1,2-hexanediol (Merck), 0.0009 g of R-40-LM (DIC Corporation), 17.95 g of PGMEA, and 8.64 g of PGME were mixed, thereby obtaining a solution having a solid content of 4.0 mass %. The solution was filtered using a polytetrafluoroethylene microfilter having a pore size of 0.2 μm to prepare a composition for forming a protective film.

Note that the amount of 1,2-hexanediol relative to the epoxy novolac resin EOCN-104S is 10 mass %.

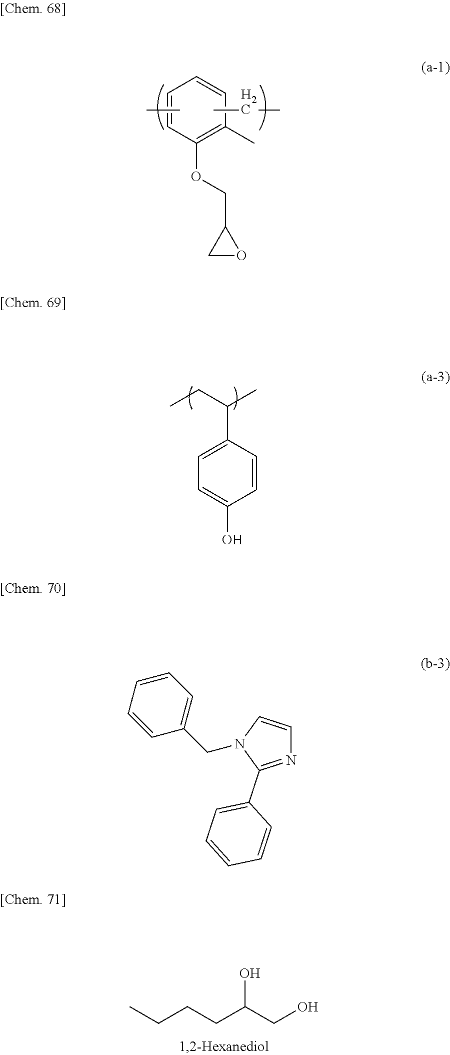

### Example 5

3.16 g (30 mass % PGMEA solution, weight average molecular weight: 3,100) of an epoxy novolac resin EOCN-104S (product manufactured by Nippon Kayaku Co., Ltd., corresponding to Formula (a-1)), 0.24 g of VP-2500 (product manufactured by Nippon Soda Co., Ltd., corresponding to Formula (a-3), weight average molecular weight: 3,687), 0.014 g of 1B2PZ (product manufactured by Shikoku Chemicals Corporation, corresponding to Formula (b-3)), 0.095 g of butyl lactate (Tokyo Chemical Industry Co., Ltd.), 0.0009 g of R-40-LM (DIC Corporation), 17.95 g of PGMEA, and 8.64 g of PGME were mixed, thereby obtaining a solution having a solid content of 4.0 mass %. The solution was filtered using a polytetrafluoroethylene microfilter having a pore size of 0.2 μm to prepare a composition for forming a protective film.

Note that the amount of butyl lactate relative to the epoxy novolac resin EOCN-104S is 10 mass %.

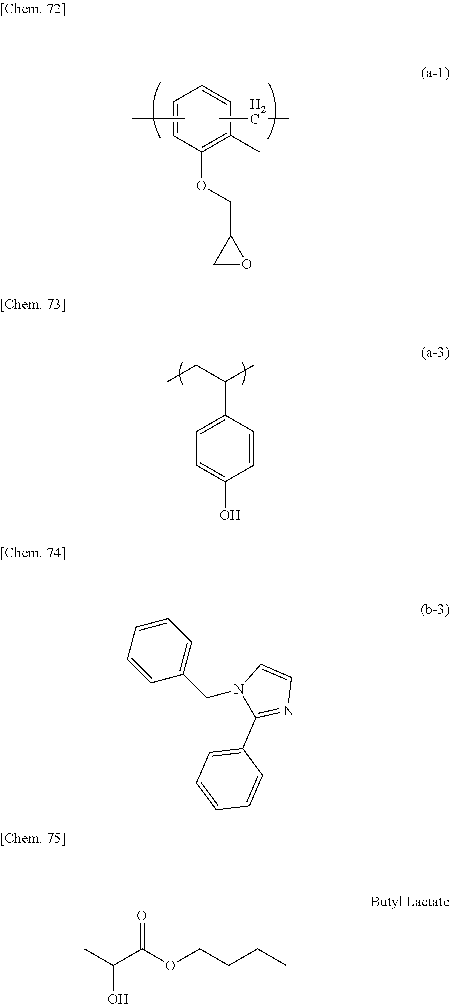

### Example 6

3.16 g (30 mass % PGMEA solution, weight average molecular weight: 3,100) of an epoxy novolac resin EOCN-104S (product manufactured by Nippon Kayaku Co., Ltd., corresponding to Formula (a-1)), 0.24 g of VP-2500 (product manufactured by Nippon Soda Co., Ltd., corresponding to Formula (a-3), weight average molecular weight: 3,687), 0.014 g of 1B2PZ (product manufactured by Shikoku Chemicals Corporation, corresponding to Formula (b-3)), 0.095 g of N-phenyldiethanolamine (Tokyo Chemical Industry Co., Ltd.), 0.0009 g of R-40-LM (DIC Corporation), 17.95 g of PGMEA, and 8.64 g of PGME were mixed, thereby obtaining a solution having a solid content of 4.0 mass %. The solution was filtered using a polytetrafluoroethylene microfilter having a pore size of 0.2 μm to prepare a composition for forming a protective film.

Note that the amount of N-phenyldiethanolamine relative to the epoxy novolac resin EOCN-104S is 10 mass %.

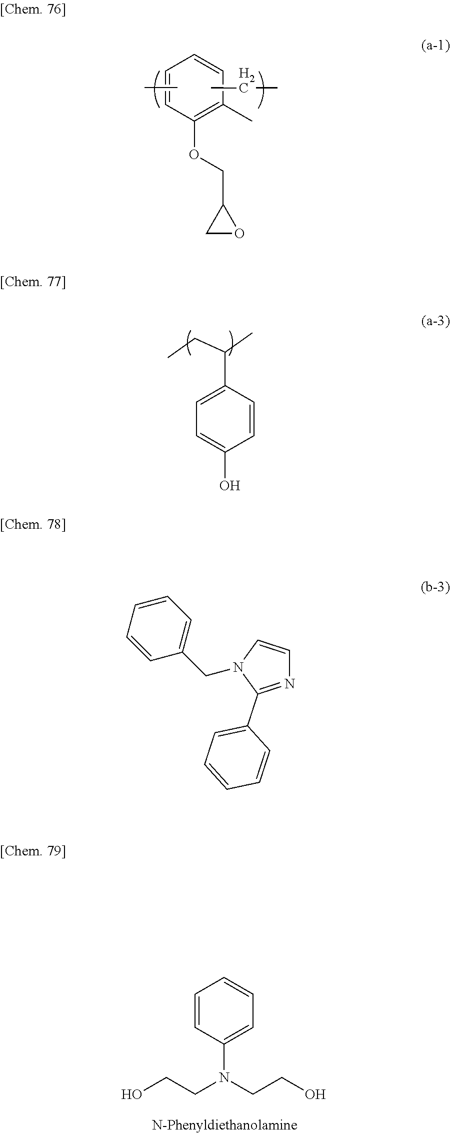

### Comparative Example 1

### Synthesis Example 1

A solution of 5.50 g of glycerin monomethacrylate (product name: BLEMMER GLM, manufactured by NOF CORPORATION), 5.09 g of 5-vinylbenzo[d][1,3]dioxole (manufactured by Cool Pharm LTD.), 0.66 g of 2,2′-azobis(isobutyronitrile) (manufactured by Tokyo Chemical Industry Co., Ltd.), and 35.99 g of propylene glycol monomethyl ether was added to a dropping funnel, the mixture was added dropwise to a reaction flask to which 9.00 g of propylene glycol monomethyl ether was added at 100° C. under a nitrogen atmosphere, and the mixture was heated and stirred for 17 hours. 11 g of a cation exchange resin (product name: DOWEX [registered trademark]550A, MUROMACHI CHEMICALS INC.) and 11 g of an anion exchange resin (product name: AMBERLITE [registered trademark]15JWET, ORGANO CORPORATION) were added to the obtained solution, and an ion exchange treatment was performed at room temperature for 4 hours. A resin solution corresponding to Formula (F) was obtained by separating the ion exchange resin, and a weight average molecular weight (Mw) measured in terms of polystyrene by GPC was 10,800.

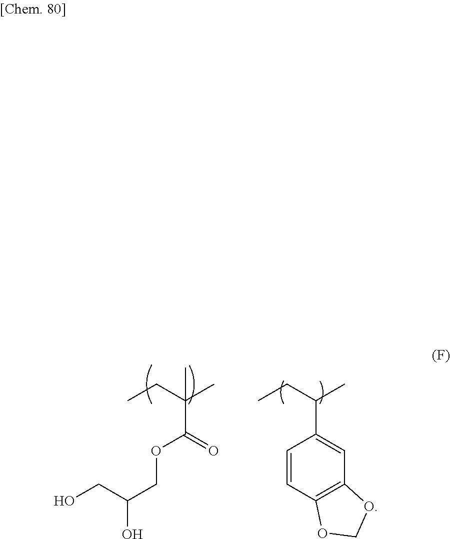

### <<Preparation of Composition for Forming Protective Film>>

To 6.6 g of the resin solution (solid content: 17.4 wt %) obtained in Synthesis Example 1, 0.06 g of pyridinium trifluoromethanesulfonic acid (manufactured by ADEKA Corporation) as a crosslinking acid catalyst, 0.001 g of a surfactant (product name: MEGAFACE [trade name]R-40, fluorine-based surfactant, manufactured by DIC Corporation), 11.5 g of PGME, and 1.9 g of PGMEA were added, thereby preparing a solution of a composition for forming a protective film.

### Comparative Example 2

3.16 g (30 mass % PGMEA solution, weight average molecular weight: 3,100) of an epoxy novolac resin EOCN-104S (product manufactured by Nippon Kayaku Co., Ltd., corresponding to Formula (a-1)), 0.24 g of VP-2500 (product manufactured by Nippon Soda Co., Ltd., corresponding to Formula (a-3), weight average molecular weight: 3,687), 0.014 g of 1B2PZ (product manufactured by Shikoku Chemicals Corporation, corresponding to Formula (b-3)), 0.0009 g of R-40-LM (DIC Corporation), 17.95 g of PGMEA, and 8.64 g of PGME were mixed, thereby obtaining a solution having a solid content of 4.0 mass %. The solution was filtered using a polytetrafluoroethylene microfilter having a pore size of 0.2 μm to prepare a composition for forming a protective film.

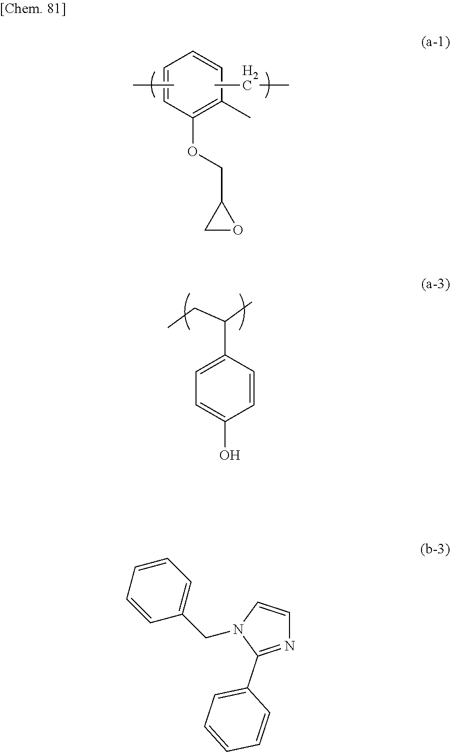

### (Formation of Coating Film)

Each of the compositions for forming a protective film prepared in Examples 1 to 6 and the compositions for forming a protective film prepared in Comparative Examples 1 and 2 was applied onto a silicon substrate having a surface on which a titanium nitride film was formed by spin coating, and baking was performed at 250° C. for 60 seconds, thereby preparing a coating film having a thickness of 100 nm.

### (Test of Resistance to Basic Hydrogen Peroxide Aqueous Solution)

The coating film prepared on the silicon substrate having the surface on which the titanium nitride film was formed using each of the compositions for forming a protective film prepared in Examples 1 to 6 and the compositions for forming a protective film prepared in Comparative Examples 1 and 2 was immersed in a basic hydrogen peroxide aqueous solution having the composition as shown in Table 1 at the temperature shown in the same table for 3 minutes 30 seconds, and then the state of the coating film after being washed with water and dried was visually observed. The results are shown in Table 2. “x” indicates a state in which the film is peeled off, “Δ” indicates a state in which a part of the film is peeled off, and “∘” indicates a state in which the film is not peeled off.

TABLE 1

| | 33 mass % of | | |
|---|---|---|---|
| 28 mass % of | hydrogen | | |
| ammonia | peroxide | | |
| aqueous | aqueous | Ultrapure | |
| solution | solution | water | Temperature |
| 40 mL | 40 mL | 80 mL | 50° C. |

TABLE 2

| Example | Example | Example | Example | Example | Example | Comparative | Comparative |
|---|---|---|---|---|---|---|---|
| 1 | 2 | 3 | 4 | 5 | 6 | Example 1 | Example 2 |
| ◯ | ◯ | ◯ | ◯ | ◯ | ◯ | X | Δ |

From the results in Table 2, it was found that the coating films prepared using the compositions for forming a protective film prepared in Examples 1 to 6 had improved resistance to a basic hydrogen peroxide aqueous solution as compared with Comparative Examples 1 and 2.

Note that the results of Comparative Example 2 were superior to those of Comparative Example 1, and the results of Examples 1 to 6 were even superior to those of Comparative Example 2.

### (Test of Optical Parameters)

Each of the compositions for forming a protective film prepared in Examples 1 to 6 and Comparative Examples 1 and 2 was applied onto a silicon wafer with a spinner. Baking was performed on a hot plate at 250° C. for 1 minute to form a resist underlayer film (film thickness: 50 nm). Then, an n value (a refractive index) and a k value (an attenuation coefficient or an absorption coefficient) of these films at a wavelength of 193 nm and a wavelength of 248 nm were measured using a spectroscopic ellipsometer (J.A. Woollam Company, VUV-VASE VU-302). The results are shown in Table 3.

TABLE 3

| | n/k@ 193 nm | n/k@ 248 nm |
|---|---|---|
| Example 1 | 1.44/0.65 | 1.90/0.02 |
| Example 2 | 1.45/0.65 | 1.89/0.03 |
| Example 3 | 1.46/0.65 | 1.89/0.03 |
| Example 4 | 1.46/0.65 | 1.89/0.03 |
| Example 5 | 1.46/0.65 | 1.89/0.03 |
| Example 6 | 1.46/0.66 | 1.89/0.03 |
| Comparative | 1.47/0.32 | 1.91/0.04 |
| Example 1 | | |
| Comparative | 1.48/0.65 | 1.88/0.02 |
| Example 2 | | |

### INDUSTRIAL APPLICABILITY

The composition for forming a protective film according to the present invention has excellent resistance when a wet etching solution is applied in substrate processing, and thus provides a protective film which is less damaged during substrate processing. The composition for forming a resist underlayer film according to the present invention has excellent resistance when a wet etching solution is applied in substrate processing.

1. A composition for forming a protective film against a wet etching solution for a semiconductor, the composition comprising:
(A) a compound or polymer having a reactive group capable of undergoing a crosslinking reaction in the presence of a curing agent;
(B) a curing agent;
(C) a compound having a hydroxy group and at least one of a hydroxy group and a carbonyl group; and
(D) a solvent.

2. The composition for forming a protective film according to claim 1, further comprising (E) a compound or polymer having a phenolic hydroxy group.

3. The composition for forming a protective film according to claim 1, wherein the curing agent is a base.

4. The composition for forming a protective film according to claim 3, wherein the base is an imidazole-based compound.

5. The composition for forming a protective film according to claim 4, wherein the base is represented by the following Formula (B1): 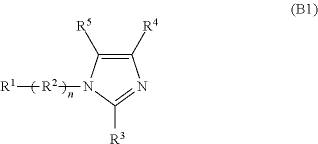
in Formula (B1), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or fewer carbon atoms, which may be substituted, R⁵ represents a hydrogen atom, a formyl group, an alkyl group having 1 to 4 carbon atoms, which may be substituted, or an alkoxyalkyl group having 4 or fewer carbon atoms, which may be substituted, and n represents 0 or 1.

6. The composition for forming a protective film according to claim 1, wherein the compound (C) is at least one of a compound represented by the following Formula (C-1), a compound represented by the following Formula (C-2), and a compound represented by the following Formula (C-3): 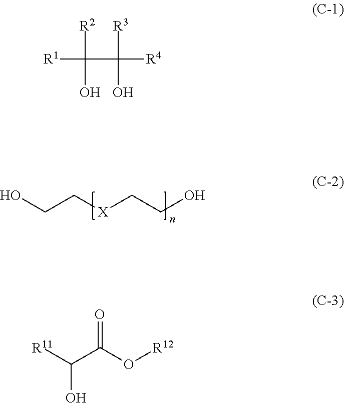
in Formula (C-1), R¹ to R⁴ each independently represent a hydrogen atom, an alkyl group having 1 to 6 carbon atoms, or a hydroxyalkyl group having 1 to 6 carbon atoms,
in Formula (C-2), X represents —O— or —NR— (R represents a hydrogen atom, an alkyl group having 1 to 6 carbon atoms, which may have a hydroxy group, an aryl group having 6 to 12 carbon atoms, which may have a substituent, or an aralkyl group having 7 to 13 carbon atoms, which may have a substituent), n represents an integer from 1 to 3, and when n is 2 or 3, X may be the same or different, and
in Formula (C-3), R¹¹ represents an alkyl group having 1 to 4 carbon atoms, and R¹² represents an alkyl group having 1 to 6 carbon atoms.

7. The composition for forming a protective film according to claim 1, wherein a content of the compound (C) is 1 to 30 mass % with respect to the compound or polymer (A).

8. The composition for forming a protective film according to claim 1, wherein the compound or polymer (A) is a compound or polymer containing a cyclic ether having a 3-membered ring structure or a 4-membered ring structure.

9. The composition for forming a protective film according to claim 8, wherein
the compound (A) is a compound that does not have a repeating structural unit,
the compound has a terminal group (A1), a polyvalent group (A2), and a linking group (A3),
the terminal group (A1) is bonded only to the linking group (A3),
the polyvalent group (A2) is bonded only to the linking group (A3),
the linking group (A3) is bonded on one hand to the terminal group (A1) and on the other hand to the polyvalent group (A2), and may optionally be bonded to another linking group (A3),
the terminal group (A1) has any of structures of the following Formula (I): 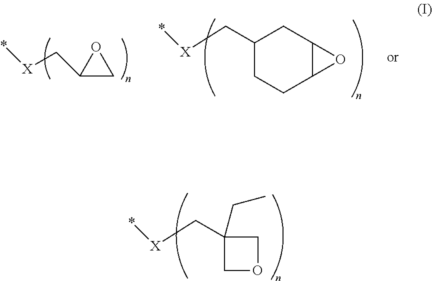
in Formula (I), * represents a binding site to the linking group (A3), and
X represents an ether bond, an ester bond, or a nitrogen atom, in which n=1 when X is an ether bond or an ester bond, and n=2 when X is a nitrogen atom,
the polyvalent group (A2) is
a divalent to tetravalent group selected from the group consisting of:
—O—;
an aliphatic hydrocarbon group;
a combination of an aromatic hydrocarbon group having fewer than 10 carbon atoms and an aliphatic hydrocarbon group; and
a combination of an aromatic hydrocarbon group having 10 or more carbon atoms and —O—, and
the linking group (A3) represents an aromatic hydrocarbon group.

10. The composition for forming a protective film according to claim 9, wherein the compound (A) is a compound represented by the following Formula (II): 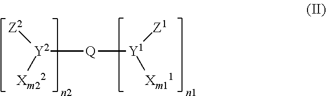
in Formula (II),
Z¹ and Z² each independently represent 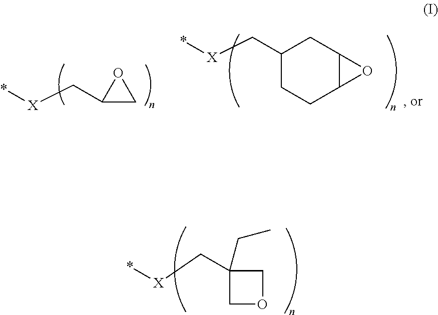
in Formula (I), * represents Y¹ or a binding site to Y², and
X represents an ether bond, an ester bond, or a nitrogen atom, in which n=1 when X is an ether bond or an ester bond, and n=2 when X is a nitrogen atom,
Y¹ and Y² each independently represent an aromatic hydrocarbon group,
X¹ and X² each independently represent —Y¹—Z¹ or —Y²—Z²,
n1 and n2 each independently represent an integer from 0 to 4, where any one of n1 and n2 is 1 or more,
m1 defined in (X¹)m1 represents 0 or 1,
m2 defined in (X²)m2 represents 0 or 1, and
Q represents a (n1+n2)-valent group selected from the group consisting of —O—, an aliphatic hydrocarbon group, a combination of an aromatic hydrocarbon group having fewer than 10 carbon atoms and an aliphatic hydrocarbon group, and a combination of an aromatic hydrocarbon group having 10 or more carbon atoms and —O—.

11. The composition for forming a protective film according to claim 9, wherein the compound (A) is a compound having a partial structure represented by the following Formula (III): 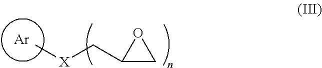
in Formula (III), Ar represents a benzene ring, a naphthalene ring, or an anthracene ring, and X represents an ether bond, an ester bond, or a nitrogen atom, in which n=1 when X is an ether bond or an ester bond, and n=2 when X is a nitrogen atom.

12. The composition for forming a protective film according to claim 8, wherein the polymer (A) is a polymer having a unit structure represented by the following Formula (1-1): 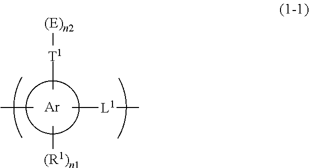
in Formula (1-1), Ar represents a benzene ring, a naphthalene ring, or an anthracene ring, R¹ represents a hydroxy group, a mercapto group which may be protected by a methyl group, an amino group which may be protected by a methyl group, a halogeno group, or an alkyl group having 1 to 10 carbon atoms, which may be substituted with or interrupted by a heteroatom and may be substituted with a hydroxy group, n1 represents an integer from 0 to 3, L¹ represents a single bond or an alkylene group having 1 to 10 carbon atoms, n2 represents 1 or 2, E represents a group having an epoxy group or a group having an oxetanyl group, T¹ represents a single bond, an ether bond, or an alkylene group having 1 to 10 carbon atoms, which may be interrupted by an ester bond or an amide bond, when n2=1, and T¹ represents a nitrogen atom or an amide bond when n2=2.

13. The composition for forming a protective film according to claim 2, wherein the compound or polymer having a phenolic hydroxy group (E) has two or more phenolic hydroxy groups.

14. The composition for forming a protective film according to claim 2, wherein the compound or polymer having a phenolic hydroxy group (E) is represented by the following Formula (2-1): 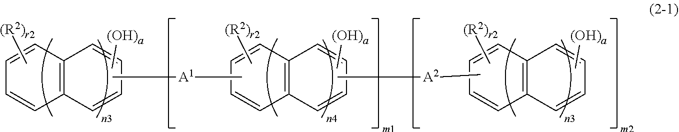
in Formula (2-1), R²'s each independently represent a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, A¹ and A² each independently represent an alkylene group having 1 to 10 carbon atoms, a divalent organic group derived from a bicyclo ring compound, a biphenylene group, a divalent organic group represented by —C(T²)(T³)-, or a combination thereof, T² represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, and T³ represents a hydrogen atom or a monovalent group represented by Formula (2-1-a), 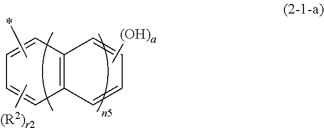
* in Formula (2-1-a) represents a binding site to a carbon atom to which T³ is bonded, R² has the same meaning as R² in (Formula 2-1), a represents an integer from 1 to 6, n3 to n5 each independently represent an integer from 0 to 2, r2 represents an integer from 0 to 3, and m1 and m2 each independently represent a number from 0 to 10,000,000.

15. The composition for forming a protective film according to claim 2, wherein the compound or polymer having a phenolic hydroxy group (E) is a compound represented by the following Formula (2-2): 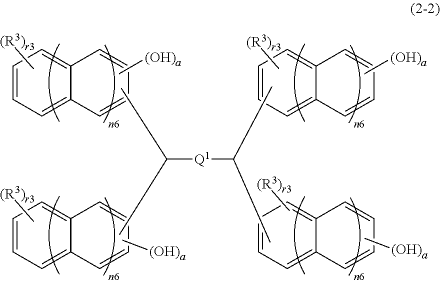
in Formula (2-2), R³ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, Q¹ represents a single bond, an oxygen atom, a sulfur atom, a sulfonyl group, a carbonyl group, an imino group, an arylene group having 6 to 40 carbon atoms, or an alkylene group having 1 to 10 carbon atoms, which may be substituted with a halogeno group, a represents an integer from 1 to 6, n6 represents an integer from 0 to 2, and r3 represents an integer from 0 to 3.

16. The composition for forming a protective film according to claim 2, wherein the compound or polymer having a phenolic hydroxy group (E) is a polymer having a unit structure represented by the following Formula (3-1): 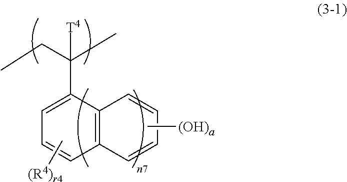
in Formula (3-1), T⁴ represents a hydrogen atom or an alkyl group having 1 to 10 carbon atoms, which may be substituted with a halogeno group, R⁴ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, r4 represents an integer from 0 to 3, n7 represents an integer from 0 to 2, and a represents an integer from 1 to 6.

17. A protective film against a wet etching solution for a semiconductor, which is a baked product of a coating film formed of the composition for forming a protective film according to claim 1.

18. A composition for forming a resist underlayer film, the composition comprising:
(A) a compound or polymer having a reactive group capable of undergoing a crosslinking reaction in the presence of a curing agent;
(B) a curing agent;
(C) a compound having a hydroxy group and at least one of a hydroxy group and a carbonyl group; and
(D) a solvent.

19. The composition for forming a resist underlayer film according to claim 18, further comprising (E) a compound or polymer having a phenolic hydroxy group.

20. The composition for forming a resist underlayer film according to claim 18, wherein the curing agent is a base.

21. The composition for forming a resist underlayer film according to claim 20, wherein the base is an imidazole-based compound.

22. The composition for forming a resist underlayer film according to claim 21, wherein the base is represented by the following Formula (B1): 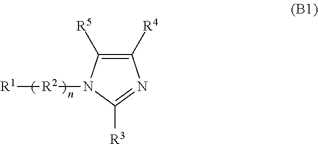
in Formula (B1), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or fewer carbon atoms, which may be substituted, R⁵ represents a hydrogen atom, a formyl group, an alkyl group having 1 to 4 carbon atoms, which may be substituted, or an alkoxyalkyl group having 4 or fewer carbon atoms, which may be substituted, and n represents 0 or 1.

23. The composition for forming a resist underlayer film according to claim 18, wherein the compound (C) is at least one of a compound represented by the following Formula (C-1), a compound represented by the following Formula (C-2), and a compound represented by the following Formula (C-3): 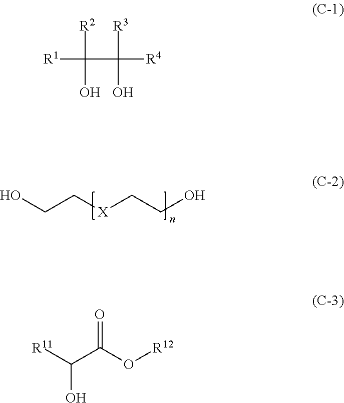
in Formula (C-1), R¹ to R⁴ each independently represent a hydrogen atom, an alkyl group having 1 to 6 carbon atoms, or a hydroxyalkyl group having 1 to 6 carbon atoms,
in Formula (C-2), X represents —O— or —NR— (R represents a hydrogen atom, an alkyl group having 1 to 6 carbon atoms, which may have a hydroxy group, an aryl group having 6 to 12 carbon atoms, which may have a substituent, or an aralkyl group having 7 to 13 carbon atoms, which may have a substituent), n represents an integer from 1 to 3, and when n is 2 or 3, X may be the same or different, and
in Formula (C-3), R¹¹ represents an alkyl group having 1 to 4 carbon atoms, and R¹² represents an alkyl group having 1 to 6 carbon atoms.

24. The composition for forming a resist underlayer film according to claim 18, wherein a content of the compound (C) is 1 to 30 mass % with respect to the compound or polymer (A).

25. The composition for forming a resist underlayer film according to claim 18, wherein the compound or polymer (A) is a compound or polymer containing a cyclic ether having a 3-membered ring structure or a 4-membered ring structure.

26. A resist underlayer film which is a baked product of a coating film formed of the composition for forming a resist underlayer film according to claim 18.

27. A method for manufacturing a substrate with a protective film, the method comprising: applying the composition for forming a protective film according to claim 1 onto a stepped semiconductor substrate and baking the composition to form a protective film, wherein the method is used for manufacturing a semiconductor.

28. A method for manufacturing a substrate with a resist pattern, the method comprising: applying the composition for forming a protective film according to claim 1 onto a semiconductor substrate and baking the composition to form a protective film as a resist underlayer film; and forming a resist film on the protective film and then performing exposure and development to form a resist pattern, wherein the method is used for manufacturing a semiconductor.

29. A method for manufacturing a semiconductor device, the method comprising: forming a protective film using the composition for forming a protective film according to claim 1 on a semiconductor substrate having a surface on which an inorganic film is optionally formed; forming a resist pattern on the protective film; dry etching the protective film using the resist pattern as a mask to expose the inorganic film or the surface of the semiconductor substrate; and wet etching and cleaning the inorganic film or the semiconductor substrate using a wet etching solution for a semiconductor using the protective film after the dry etching as a mask.

30. A method for manufacturing a semiconductor device, the method comprising: forming a resist underlayer film using the composition for forming a resist underlayer film according to claim 18 on a semiconductor substrate having a surface on which an inorganic film is optionally formed; forming a resist pattern on the resist underlayer film, dry etching the resist underlayer film using the resist pattern as a mask to expose the inorganic film or the surface of the semiconductor substrate; and etching the inorganic film or the semiconductor substrate using the resist underlayer film after the dry etching as a mask.
